(19) United States
(12) Patent Application Publication
(10) Pub. No.: US 2026/0180064 A1
(43) Pub. Date: Jun. 25, 2026

(54) SYSTEMS AND METHODS FOR ELECTRICAL ENERGY STORAGE CELL TEMPERATURE MONITORING

(71) Applicant: Instagrid GmbH, Ludwigsburg (DE)

(72) Inventors: Raphael Zürner, Ludwigsburg (DE); Philipp Gutknecht, Ludwigsburg (DE); Wolf Zahn, Ludwigsburg (DE)

(21) Appl. No.: 19/541,816

(22) Filed: Feb. 17, 2026

Related U.S. Application Data
(63) Continuation of application No. PCT/EP2025/057152, filed on Mar. 17, 2025.

(30) Foreign Application Priority Data
Mar. 26, 2024 (EP) 24166260.0
Apr. 12, 2024 (EP) 24169849.7
Feb. 26, 2025 (WO) PCT/EP2025/055209

(51) Int. Cl. H01M 10/63; H01M 10/48; H01M 10/613

(52) U.S. Cl. CPC H01M 10/63; H01M 10/482; H01M 10/613

(57) ABSTRACT

It is disclosed an energy module, comprising: electrical energy storage cells; temperature sensors configured to monitor temperatures of the electrical energy storage cells; a measurement tap in the network, which has a voltage value that will change responsive to a change of the shared current or voltage; and a circuit configured to detect an occurrence of a temperature error that is associated with one or more of the energy storage cells based on the voltage value at the measurement tap. Related methods and software products are also disclosed.

### CROSS-REFERENCE TO RELATED APPLICATIONS

The present application claims priority to and the benefit of European Patent Application No. 24166260.0, filed on Mar. 26, 2024, European Patent Application No. 24169849.7, filed on Apr. 12, 2024, and PCT Application No. PCT/EP2025/055209, filed on Feb. 26, 2025, the contents of which are incorporated herein by reference in their entirety.

### BACKGROUND

### Description of the Related Art

Battery cell packs are often used to power electronic devices. The temperature of the battery cells thereof may be monitored during use of the same. Pinned or wired temperature sensors are often used for the temperature measurements. These temperature sensors are typically mounted in a way that a battery cell temperature is coupled strongly therewith. In this regard, each temperature sensor is manually placed at a position near the battery cell(s). Thereafter, the pins or wires of the temperature sensor may be soldered to a respective pad on a circuit board. In effect, the manufacturing process of the battery cell device is relatively manually intensive, inefficient, time consuming and costly.

### SUMMARY

The present disclosure concerns an energy module. The energy storage module comprises: a plurality of electrical energy storage cells; a plurality of temperature sensors configured to monitor temperatures of the plurality of electrical energy storage cells (wherein the plurality of temperature sensors are arranged in a network such that each temperature sensor shares a current or voltage with at least another temperature sensor in the plurality of temperature sensors); a measurement tap in the network, which has a voltage value that will change responsive to a change of the shared current or voltage, wherein the change in the shared current or voltage is caused by the temperatures of the plurality of electrical energy storage cells being monitored; and a circuit configured to detect an occurrence of a temperature error that is associated with one or more of the plurality of energy storage cells based on the voltage value at the measurement tap.

The present disclosure also concerns implementing systems and methods for operating an energy module. The methods comprise: monitoring temperatures of a plurality of electrical energy storage cells respectively by a plurality of temperature sensors (wherein plurality of temperature sensors are arranged in a network such that each temperature sensor shares a current or voltage with at least another temperature sensor in the plurality of temperature sensors); allowing a voltage value at a measurement tap to change responsive to a change of the shared current or voltage, wherein the change in the shared current or voltage is caused by the temperatures of the plurality of electrical energy storage cells being monitored; and comparing the voltage value to a reference voltage to detect an occurrence of a temperature error that is associated with one or more of the plurality of electrical energy storage.

### BRIEF DESCRIPTION OF THE DRAWINGS

The present solution will be described with reference to the following drawing figures, in which like numerals represent like items throughout the figures.

FIG. 1 provides a perspective view of a power supply.

FIG. 2 provides an illustrative block diagram of the power supply shown in FIG. 1.

FIG. 3 provides a perspective view of an energy module of the power supply shown in FIG. 1.

FIG. 4 provides an assembly view of the energy module shown in FIG. 3.

FIG. 5 provides an illustrative block diagram of a circuit in the energy module shown in FIGS. 3-4.

FIGS. 6-7 provide illustrations of an energy module that are useful for understanding a conventional placement of a temperature sensor therein.

FIGS. 8-10 provide illustrations that are useful for understanding an energy module circuit with a surface mount temperature sensor in accordance with the present solution.

FIG. 11 provides an illustration of another energy module circuit with a surface mount temperature sensor in accordance with the present solution.

FIG. 12 provides an illustration of an energy module circuit with an electrically isolating and thermally conductive member connected between a surface mount temperature sensor and a conductive terminal.

FIGS. 13A-13B (collectively referred to herein as “FIG. 13”) provide illustrations of thermal isolation features.

FIGS. 14A-14B (collectively referred to herein as “FIG. 14”) provide illustrations showing an energy module circuit having a plurality of conductive terminal and temperature sensors.

FIGS. 15A-15B (collectively referred to herein as FIG. 15) each provides an illustrative circuit diagram for an energy module.

FIG. 16 provides a graph showing a qualitative correlation between two temperatures represented by two parallel thermistors and a fixed threshold temperature value. This specific qualitative correlation in FIG. 16 is valid for a circuit of two negative temperature coefficient (NTC) thermistors in parallel (shared voltage).

FIG. 17 provides another illustrative circuit diagram for an energy module.

FIG. 18 provides yet another illustrative circuit diagram for an energy module.

FIG. 19 provides a flow diagram of an illustrative method for operating an energy module.

FIG. 20 provides a flow diagram of another illustrative method for operating an energy module.

FIG. 21 provides a block diagram of an electrical power unit with a monitoring system.

FIG. 22 provides a block diagram of battery module shown in FIG. 21.

FIG. 23 provides a flow diagram of another method for operating an energy module.

### DETAILED DESCRIPTION

The present solution is described with reference to the attached figures. The figures are not drawn to scale and they are provided merely to illustrate the instant solution. Several aspects of the present solution are described below with reference to example applications for illustration. It should be understood that numerous specific details, relationships, and methods are set forth to provide a full understanding of the present solution. One having ordinary skill in the relevant art, however, will readily recognize that the present solution can be practiced without one or more of the specific details or with other methods. In other instances, well-known structures or operations are not shown in detail to avoid obscuring the present solution. The present solution is not limited by the illustrated ordering of acts or events, as some acts may occur in different orders and/or concurrently with other acts or events. Furthermore, not all illustrated acts or events are required to implement a methodology in accordance with the present solution.

It should also be appreciated that the terminology used herein is for the purpose of describing particular embodiments only and is not intended to be limiting of the present solution. As used herein, the singular forms “a”, “an” and “the” are intended to include the plural forms as well, unless the context clearly indicates otherwise. Furthermore, to the extent that the terms “including”, “includes”, “having”, “has”, “with”, or variants thereof are used in either the detailed description and/or the claims, such terms are intended to be inclusive in a manner similar to the term “comprising.”

Further, unless otherwise defined, all terms (including technical and scientific terms) used herein have the same meaning as commonly understood by one of ordinary skill in the art to which this solution belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As noted above, conventional manufacturing processes of battery cell devices are relatively manually intensive, inefficient, time consuming and costly. Thus, there is a need for a battery cell design that facilitates an improved manufacturing process. The present solution is directed to a novel temperature sensor design that allows for an improved manufacturing process for battery devices with a cell temperature monitoring feature.

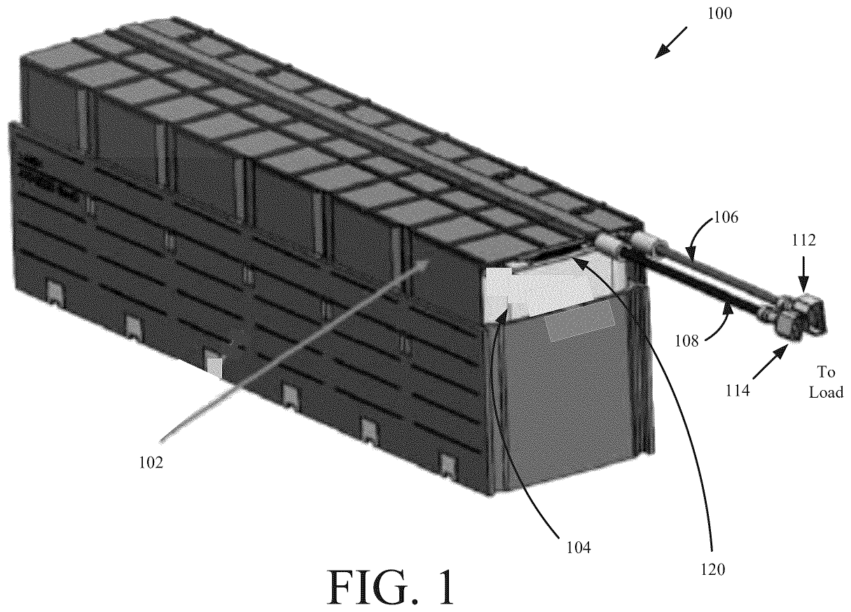

FIG. 1 provides an illustration of a power supply 100 which may be portable or otherwise mobile. The power supply 100 may have a size and weight to allow a single individual to carry the same with relative ease and/or to allow the same to be carried in a backpack or other bag. Power supply 100 may be connected in series or parallel with other power supplies to form a power supply unit.

Power supply 100 is generally configured to supply electric power to a load (not shown in FIG. 1). The load can include any electronic device that needs to be supplied power. Such loads can include, but are not limited to, another power supply, communication devices, media devices, golf carts, electric appliances, computing devices, and/or professional or home energy storage systems.

As shown in FIG. 1, the power supply 100 comprises a housing 102 in which a plurality of energy modules 104 are housed. Each energy module 104 is generally configured to convert direct current (DC) outputs from internal electrical energy storage cells into an alternating current (AC) output of the energy module. The electrical energy storage cells can include, but are not limited to, battery cells and/or super capacitors. The energy modules 104 are electrically connected to each other via insulated wires 106, 108. In this way, the AC outputs of the energy modules are combined or otherwise summed together to produce the AC output power of the power supply 100. More specifically, the energy modules 104 are connected in series in a controllable manner to supply different voltages at the output of the power supply 100. Connectors 112, 114 are provided at the distal ends of insulated wires 106, 108 to provide a means to connect the output of the power supply 100 to the load.

In some uses, more than one instance of the power supply 100 may be coupled together to obtain a larger capacity power supply and/or a multi-voltage power supply. Such plurality of instances of the power supply 100 may, for example, be enclosed in a common housing (not shown in FIG. 1). It is further possible to obtain multi-phase power supplies using multiple instances of the power supply 100. It shall be appreciated that such arrangements may further benefit from a reliable thermal monitoring of the electrical energy storage cells which are packed together.

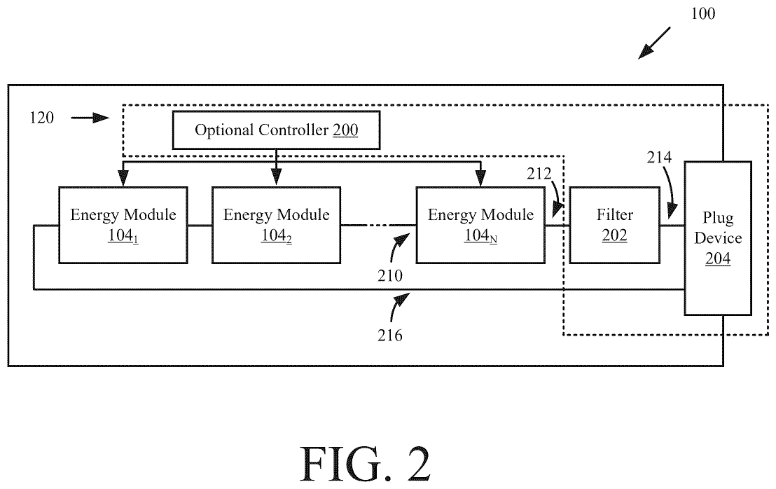

Operation of the energy modules 104 may be controlled using an internal circuit 120. An illustrative technique for controlling the energy modules will now be discussed in relation to the block diagram of FIG. 2. The energy modules are referred to in FIG. 2 by reference numbers 104₁, 104₂, . . . , 104_{N}. The energy modules 104₁, 104₂, . . . , 104_{N} are collectively referred to herein as energy modules 104. N is an integer equal to or greater than one.

As shown in FIG. 2, circuit 120 may comprise an optional controller 200, a filter 202 and a plug device 204. Controller 200 may reside external to the power supply 100 in some scenarios in which the power supply 100 comprises part of a grid. The grid can include a plurality of power supplies that are connected to each other and controlled by a unit controller. Controller 200 is shown internal to the power supply 100 for ease of illustration and explanation of the system operations. However, the present solution is not limited to the shown configuration. The plug device 204 may include the wires (e.g., wires 106, 108 of FIG. 1), connectors (e.g., connectors 112, 114 of FIG. 1), and/or other components to facilitate the supply of power to a load. For example, lines 214, 216 may correspond to wires 112 and 114.

The controller 200 is configured to selectively activate and deactivate the energy modules 104 for causing the power supply 100 to deliver AC power to the load with the correct voltage, current and frequency. The controller 200 is connected to each of the energy modules 104₁, 104₂, . . . , 104_{N} so that the energy modules can be controlled individually thereby. The controller 200 is configured to selectively transition each energy module between a battery mode and a bypass mode. When an energy module is in its battery mode, the internal electrical energy storage cells are switched into the circuit such that they are connected between terminals 210, 212 thereof. As such, a voltage output from the electrical energy storage cells is provided at terminal 210 and 212. In contrast, when the energy module is in a bypass mode, the internal electrical energy storage cells are bypassed such the terminals 210, 212 are directly shortened to each other. In effect, no voltage from the electrical energy storage cells is provided at terminal 210 or 212 of the energy module.

Particularly, an energy module may provide the following operation modes: a Hi-Z (high impedance) mode in which module output is set to a high-impedance state (e.g., associated with none of the switches in the module being turned ON); a bypass mode in which the energy module is not contributing any battery voltage, but letting the current flow via it (e.g., via both low-side switches of the H-bridge being turned ON); a conducting+mode in which the electrical energy storage cells are connected to the module output in a given polarity; and a conducting-mode in which the electrical energy storage cells are connected to the module output in an opposite polarity as compared to the conducting+mode.

By successively transitioning the energy modules from the bypass mode to the battery mode, the combined output voltage of the energy modules 104 can be increased in steps. Similarly, by successively transitioning the energy modules from the battery mode to the bypass mode, the combined output voltage of the energy modules 104 can be decreased in steps. The combined output voltage can be changed by an amount equal to the output voltage V_{M} of one energy module. Thus, the combined output voltage V_{C} can vary between zero volts and N times V_{M} Volts (i.e., 0 Volts<V_{C}<N·V_{M} Volts). For obtaining finer transition between the V_{M} steps, at least one energy module can be operated in a pulse-width-modulation (PWM) mode with time varying duty-cycle. The combined output voltage V_{C} can be smoothed by filter 202 so as to produce a voltage signal on line 214. The voltage signal on line 214 may have sinusoidal characteristics, DC signal characteristics or other waveform characteristics.

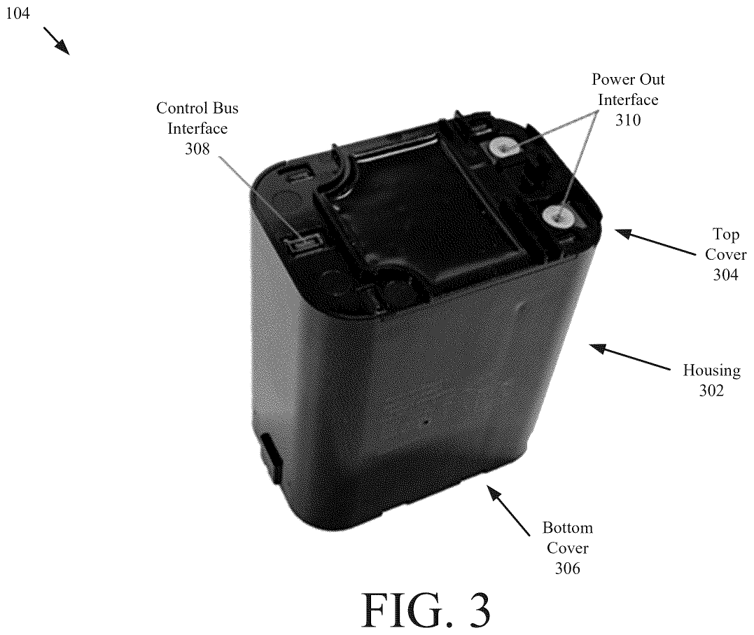

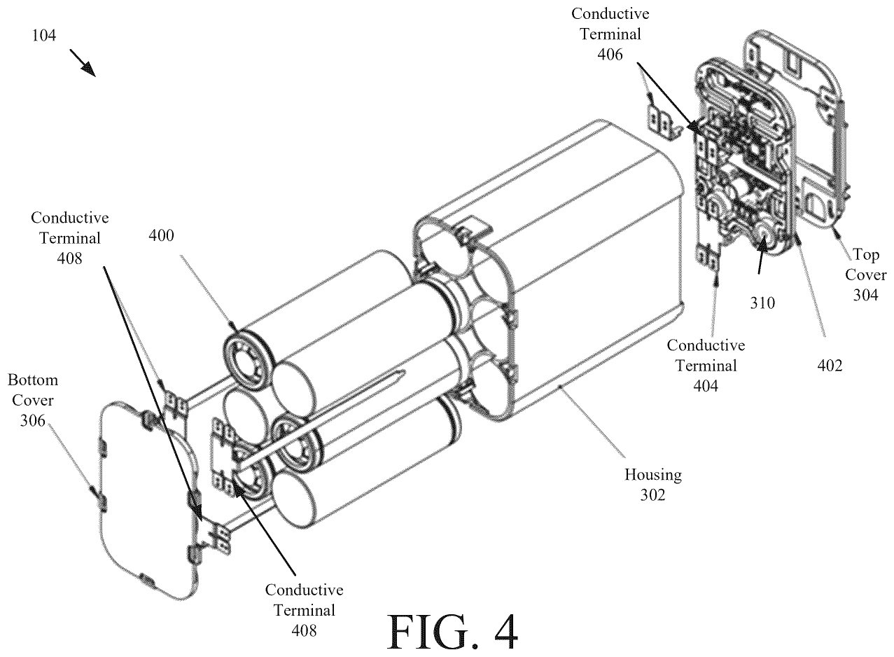

FIG. 3 provides an illustration of an energy module 104. An assembly view of the energy module 104 is provided in FIG. 4. Energy modules 104 of FIGS. 1 and 104₁, 104₂, . . . , 104_{N} of FIG. 2 may be the same as or similar to the energy module shown in FIG. 3.

Energy module 104 comprises a housing 302 in which electrical energy storage cells 400 are housed so as to maintain certain positions relative to each other. The electrical energy storage cells 400 can be arranged in two rows of three cells as shown in FIGS. 3-4. The present solution is not limited in this regard. The electrical energy storage cells can have a different arrangement than that shown in FIGS. 3-4. Any number of electrical energy storage cells can be provided in the energy module in accordance with a given application. Each electrical energy storage cell may include, but is not limited to, a lithium-ion cell. Hence, the energy module 104 may comprise electrical energy storage cells which are in the form of an electrical battery, capacitor or supercapacitor, their likes or their combinations. The electrical energy storage cell, lithium-ion cell, may have a cylindrical shape as shown or another shape (e.g., a rectangular shape) not shown.

A top cover 304 and a bottom cover 306 are provided for the housing 302. The covers 304, 306 may be configured to provide an environment seal with the housing 302. The environmental seal may be facilitated by gaskets (not visible or shown in FIGS. 3-4) compressed between the covers 304, 306 and the housing's sidewalls. The module 100 also comprises a power out interface 310.

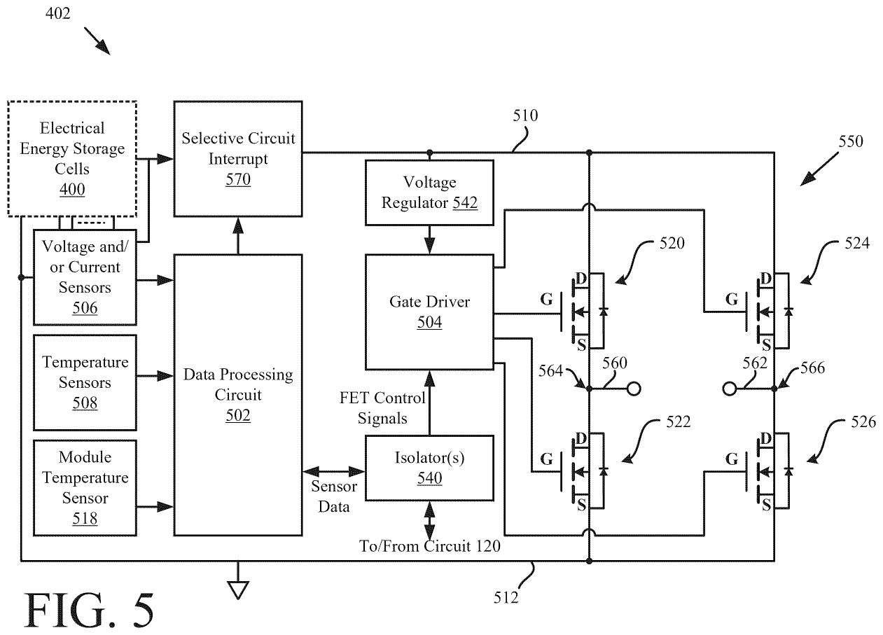

The safe and reliable operation of the energy module 104 may require the constant monitoring of each electrical energy storage cell 400 to detect when its current, voltage and/or temperature fall outside of defined operating range(s). This monitoring is achieved using a circuit 402 that may also be housed in the housing 302. Conductive terminals 404, 406, 408 are provided to connect the electrical energy storage cells 400 to the circuit 402 for at least voltage measurements. In some non-limiting examples, the conductive connectors 404 may also be used for leading operationally generated heat away from the circuit 402 (e.g., heat generated by switching elements) preferably away from the module 104. Alternatively or in addition, some non-limiting examples, the circuit 402 may be arranged such that the storage components 400 are also used for leading operationally generated heat away from the circuit 402. For example, a thermal coupling (e.g., passive and/or active, such as gas or fluid cooled) may be provided between the circuit 402 and one or more of the storage components 400. Alternatively or in addition, as some non-limiting examples, the power out interface 310 may be used for leading operationally generated heat away from the circuit 402. For example, conductive connectors 404 are realized in electrically conductive materials such as metal. Usually electrical conductors are also good thermal conductors. This can be leveraged to also act as heat sinks or heat pipes for transporting operationally generated heat (e.g., heat generated when the switching components are conducting current) away from the circuit 402. It shall be appreciated that either alone or in any combination, these measures can make the module 400 more compact, and in some cases also allow hermetically sealing of the module 400. This can further result in a more compact system which uses one or more of such modules 400. These measures can also result in a module and/or system comprising one or more modules that do not require active cooling (e.g., a fan or any other types of additional component or medium used for cooling). A more detailed block diagram of circuit 402 is provided in FIG. 5. It shall be appreciated that it is desirable to keep the module 104 compact and light-weight.

As shown in FIG. 5, circuit 402 comprises voltage and current sensors 506 connected to the electrical energy storage cells 400 (shown in dotted lines). These sensors 506 are configured to measure the voltage and/or current of each electrical energy storage cell. Circuit 402 may also comprise temperature sensors 508 and a module temperature sensor 518. Each temperature sensor 508 is configured to measure a temperature of one or more electrical energy storage cells, while the module temperature sensor 518 is configured to measure an internal temperature of the energy module. More specifically, the temperature sensor senses the temperature close to the power stage consisting of FETs 520, 522, 522, 526. These sensor measurements are communicated from the sensors 506, 508, 518 to the data processing circuit 502 for processing and measurement acquisition. The data processing circuit 502 can perform operations to communicate sensor measurements as sensor data to circuit 402, and/or perform operations to analyze the sensor measurements to determine if certain criteria is met. For example, if a parameter measurement falls outside of defined range at a given time or for a certain amount of time, then the data processing circuit 502 causes the circuit interrupt 570 to transition from a closed state to an open state such that the power input and output of the energy module 104 is turned off. The parameter measurement can include a voltage measurement, a current measurement or a temperature measurement.

The circuit 402 also comprises a gate driver 504 and a switching circuit, shown here in a non-limiting manner as transistor active bridge 550. Switching circuit comprises at least one switching element. As some non-limiting examples, the switching circuit may be realized as a bridge topology comprising switching elements, e.g., as a full H-bridge or a half H-bridge. The switching circuit may be in any form e.g., which facilitates electrical connection of one or more of the storage components 400 to the electrical connection 560 and/or 562. The switching circuit or the transistor active bridge circuit 550 is supplied a DC waveform from the electrical energy storage cells 400. As such, the transistor active bridge 550 is connected to electrical energy storage cells 400 via input lines 510, 512. The transistor active bridge 550 is also connected between a pair of output lines 560, 562. The output lines 560, 562 are connected to the power interface 210/212 of FIGS. 2 and/or 310 of FIG. 3.

The transistor active bridge 550 includes a plurality of switches, shown in this example as field-effect transistors (FETs) 520, 522, 524, 526 of an N-channel type. Each of the FETs may comprise a metal-oxide semiconductor FET (MOSFET). Alternatively, other kinds of switches are also possible, such as but not limited to bipolar junction transistor (BJT) or insulated gate bipolar transistor (IGBT) based switches, or even relays. Each FET 520, 522, 524, 526, in this example, has three (3) terminals respectively defined as a source S, a gate G and a drain D. An electrical path is provided from the source to the drain of each FET 520, 522, 524, 526. This path is generally referred to herein as the source-drain path. A source-drain path of first FET 520 is connected in series with a source-drain path of the second FET 522. The series connected transistor pair 520, 522 form a first series transistor combination that is connected across the input lines 510, 512. A source-drain path of the third FET 524 is connected in series with a source-drain path of the fourth FET 526 to form a second series transistor combination connected across the input lines 510, 512.

The transistor active bridge 550 can have an output defined by output lines 560, 562. A first one of the output lines 560 can be connected to the first series combination 520, 522 at an interconnection point 564 between the first and the second field-effect transistors 520, 522. A second one of the output lines 562 can be connected to the second series combination 524, 526 at an interconnection point 566 between the third and fourth field-effect transistors 524, 526.

Gate driver 504 is provided for driving the gate G of each FET 520, 522, 524, 526. In this regard, the gate driver is configured to supply a voltage to the gate G of each FET at certain times for switching the FET to its “on” state or “off” state. The gate driver is also configured to stop supplying the voltage to the gate G of the FET at certain times for switching the FET to its “on” state or “off” state. Gate driver circuits are well known. Known or to be known gate driver circuit can be used here. In some cases, the gate driver 504 may be realized as different circuits for each or some of the FETs 520, 522, 524, 526.

When the gate driver 504 communicates gate control signals to the FETs 520, 526, the FETs 520, 526 will be biased and switch to their “on” states, thus providing voltage from the energy storage cells 400 at the output lines 560, 562. In effect, current may flow between the drain D and source S of these FETs to supply a load connected between the output lines 560, 562. The FETs 520, 526 transition back to their “off” states when the gate control signals are no longer being output from the gate driver circuit. Similarly, when the gate driver 504 communicates gate control signals to the FETs 522, 524, the FETs 522, 524 will be biased and switched to their “on” states, thus providing voltage from the energy storage cells 400 at the output lines 560, 562 but in the opposite polarity as compared to the “on” state of the FETs 520 and 526. In effect, current may flow between the drain D and source S of these FETs 522, 524 to supply a load connected between the output lines 560, 562. It shall be appreciated that the load will experience current in opposite polarity in case FETs 522, 524 are “on”, as compared to the case when FETs 520, 526 are “on”. The FETs 522, 524 transition back to their “off”′ states when the gate control signals are no longer being output from the gate driver. The gate driver may be configured to prevent the two FETs in each series pair 520/526 and 522/524 from being closed simultaneously or concurrently.

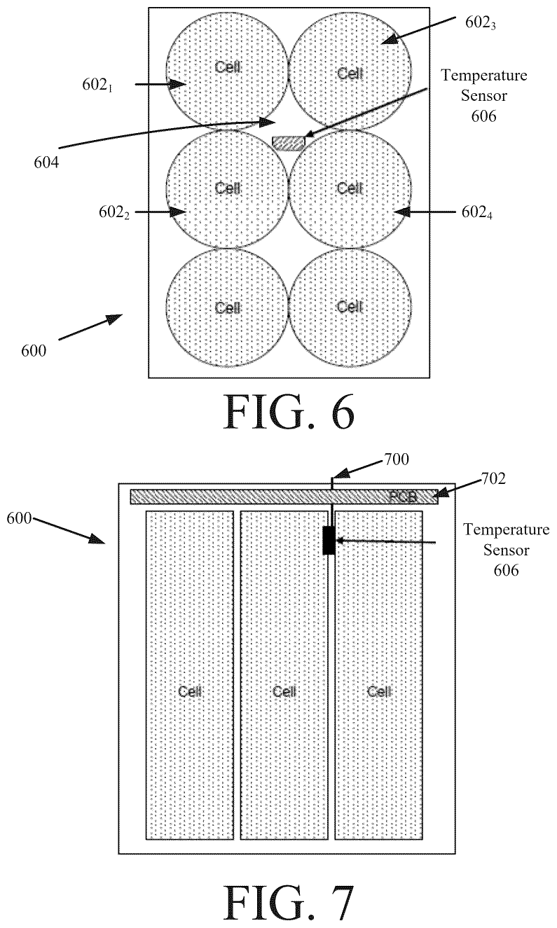

The manufacturing process of conventional energy modules is relatively manually intensive, inefficient, time consuming and costly. This is at least partially due to the use of wired or pinned temperature sensors for cell temperature measurements. FIGS. 6-7 provide illustrations that are useful for understanding the conventional temperature sensor architecture of an energy module. This conventional architecture comprises a temperature sensor 606 that is mounted so as to extend into an empty space 604 between electrical energy storage cells 602₁, 602₂, 602₃, 602₄ (e.g., cells 400) and so as to be located proximate to electrical energy storage cells 602₂, 602₄. In this way, the temperature of electrical energy storage cells 602₂, 602₄ are coupled with the temperature sensor 606. For example, the temperature sensor 606 can include a through-hole-technology (THT) sensor. The pin(s) 700 of the temperature sensor 606 is soldered to a circuit board 702. The placement of the temperature sensor 606 amongst the electrical energy storage cells and the soldering of the temperature sensor 606 to the circuit board 702 are manually performed during a manufacturing process of the energy module 600. It shall be appreciated that energy module 600 may be the same as the module 104.

The present solution provides a novel temperature sensor architecture for an energy module that eliminates the need for a pined temperature sensor in an energy module and therefore also eliminates the manual process. This is achieved through the use of a surface mount (SMT) sensor for measuring cell temperature. The SMT sensor is more suitable for an automated manufacturing process for the energy module with a minimized cost and time.

It should be noted that the SMT temperature sensor mounted on a circuit board may be more influenced by temperature sources on the same circuit board rather than by the electrical energy storage cells. Moreover, a farther proximity of an SMT sensor from the electrical energy storage cells may cause reduction in temperature measurement capability or reliability. Thus, the present solution addresses this issue by maximizing the thermal conductivity from the SMT temperature sensor to the electrical energy storage cell and minimizes the thermal conductivity from SMT temperature sensor to other temperature sources on the circuit board. The manner in which this is accomplished will become evident as the discussion progresses. However, in general, this is achieved with SMT temperature placement, circuit board layout, use of cell voltage sense connections and/or other optional aspects to improve or reduce thermal conductivity in one or other direction.

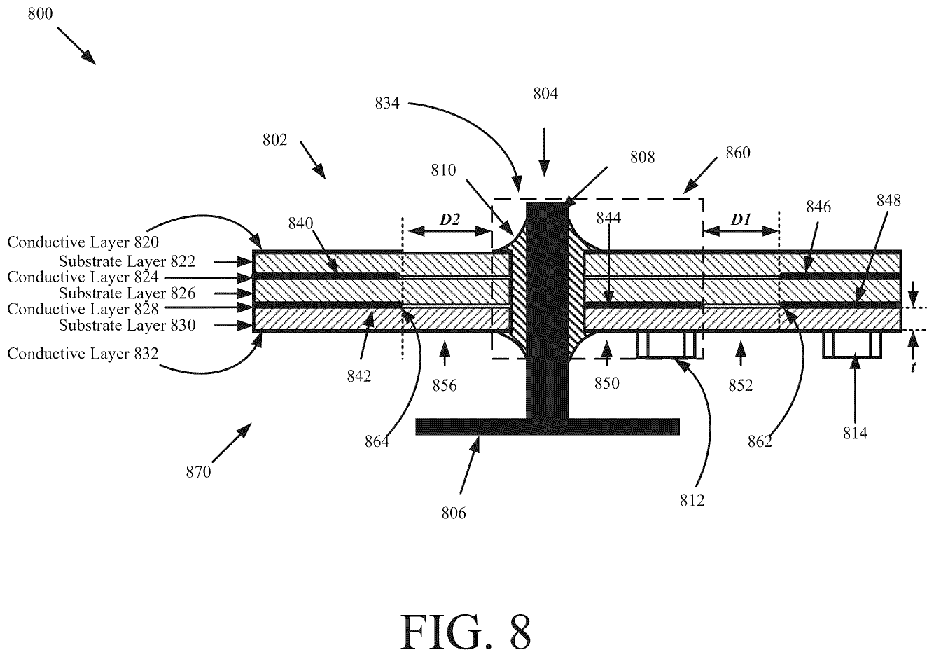

FIG. 8 provides a perspective view of an illustrative architecture for an internal circuit 800 of an energy module. The energy module can include, but is not limited to, energy module 104 of FIG. 1, energy module 104₁, . . . , 104_{N} of FIG. 2, or the energy module of FIG. 3. The circuit 402 of FIGS. 4-5 can be the same as or similar to circuit 800 of FIG. 8.

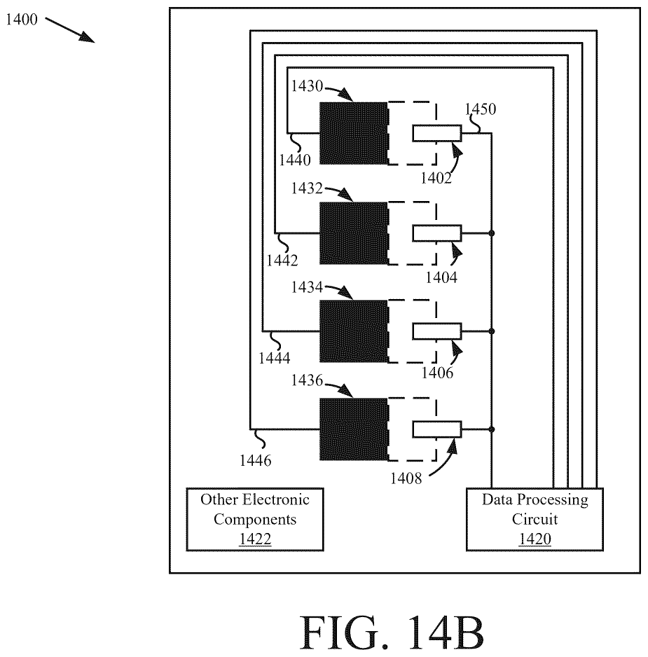

As seen in FIG. 8, internal circuit 800 will be described in relation to a single conductive terminal 804 and a single temperature sensor 812 for simplicity of discussion. Conductive terminal 804 can be configured to facilitate cell voltage measurements. In other words, the main purpose of the conductive terminal 804 may be to provide electrical signals at the internal circuit 800. However, it should be understood that internal circuit 800 can include any number of conductive terminals and temperature sensors selected in accordance with a particular application. For example, as shown in a top view of FIG. 14, the circuit can include four conductive terminals and four temperature sensors. The present solution is not limited to the particulars of FIG. 14. The following discussion is sufficient for understanding the architecture for each pair of components 804, 812 provided with an internal circuit of an energy module.

It should also be noted that a data processing circuit (e.g., data processing circuit 502) is electrically connected to the conductive terminal 804 and the temperature sensor 812 so that voltage and temperature measurements can be received thereby. The data processing circuit is configured to detect when voltage and temperature measurements fall outside of pre-specified ranges. The data processing circuit and these electrical connections are not shown in FIG. 8 for ease and simplicity of illustration.

The conductive terminal 804 comprises a distal end 806 that can be welded or otherwise coupled to electrical energy storage cells. The conductive terminal 804 can include, but is not limited to, conductive terminal 404 of FIG. 4. The temperature sensor 812 can include, but is not limited to, a surface mount thermistor or other surface mount temperature sensor.

In addition to the components 804 and 812, circuit 800 comprises other electronic component(s) 814 mounted on a multi-layer circuit board 802. The electronic component(s) can include, but are not limited to, resistor(s), capacitor(s), inductor(s), amplifier(s), filter(s), selective circuit interrupt(s) (e.g., selective circuit interrupt 570 of FIG. 5), voltage regulator(s) (e.g., voltage regulator 542 of FIG. 5), isolator(s) (e.g., isolators 540 of FIG. 5), processor(s) (e.g., data processing circuit 502 of FIG. 5), gate driver(s) (e.g., gate driver 504 of FIG. 5), a transistor active bridge circuit (e.g., transistor active bridge circuit 550 of FIG. 5).

Multi-layer circuit board 802 comprises substrate layers 822, 826, 830 and conductive layers 820, 824, 828, 832. The exact number of layers which the circuit board 802 has is not essential or limiting to the present teachings. Substrate layers 822, 826, 830 are formed of the same or different dielectric material. Each of the conductive layers 820, 824, 828, 832 may comprise one or more conductors 840, 842, 844, 846, 848 formed thereon. Conductors 840, 842, 844, 846, 848 can include, but are not limited to, traces.

A through-hole pad 834 is formed through the circuit board 802. A connection member 808 of the conductive terminal 804 extends through the through-hole pad 834. Solder may be used to couple the connection member 808 to the circuit board 802 and provide an electrical connection between the conductive terminal 804 and conductor 844. This connection is referred to as a conductive connection 810. The conductive connection 810 can include, but is not limited to, a solder joint.

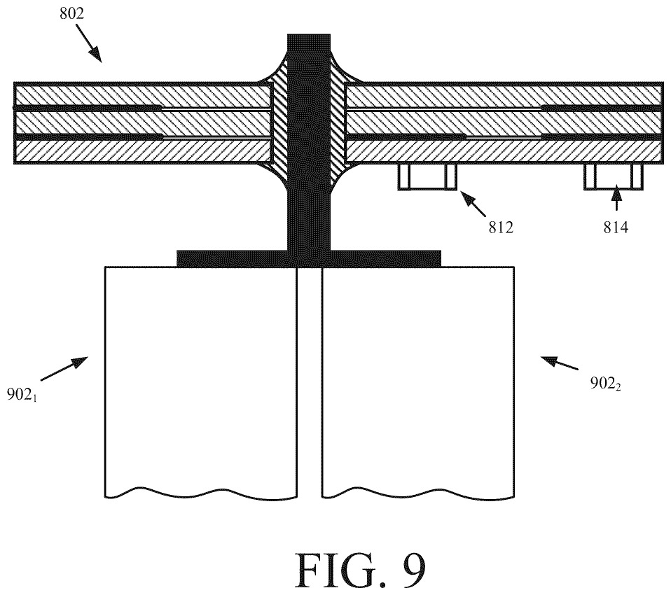

The temperature sensor 812 is mounted on a side 870 of the circuit 800 which faces the electrical energy storage cells 902₁, 902₂ when the energy module is assembled as illustrated in FIG. 9. The temperature sensor 812 is located proximate to the conductive terminal 804 and conductor 844 so that it can detect the temperature of the electrical energy storage cells 902₁, 902₂ via the conductive terminal 804. Since the distal end 806 of the conductive terminal 804 is conductively connected directly to the electrical energy storage cells 902₁, 902₂, the conductive terminal 804 also provides relatively good thermal conductivity suitable for cell temperature measurements, while providing the main purpose of relatively good electrical conductivity suitable for cell voltage measurements. Hence, an electrical component having the main purpose of establishing electrical connection is further leveraged to obtain more accurate temperature measurements in a non-contact fashion with a device-under-monitoring. It shall be appreciated that the “device-under-monitoring” in this case would be one or more of the electrical energy storage cells.

It should be noted that the temperature sensor 812 is electrically not directly connected to the conductive terminal 804. An electrical isolation between the temperature sensor 812 and the conductive terminal 804 is facilitated by the design of the multi-layer circuit board 802, the relative positions of the two components 804, 812, and the relative positions of components 812, 844. First, the thickness t of the substrate layer 830 is selected to be relatively thin. For example, this thickness t is selected to be less than 0.2 mm in some scenarios to ensure that conductive layers 828, 832 are located relatively close to each other. Second, a conductive trace or plane 844 is disposed on conductive layer 828 (i) so as to be electrically connected to the conductive terminal 804 via conductive connection 810 and (ii) so that it resides directly in proximity to (e.g., above) the temperature sensor 812. The size, shape and/or material of the conductive plane 844 can be selected to maximize thermal conductivity to the temperature sensor 812. For example, the conductive plane 844 may substantially overlap or extend the region occupied by the temperature sensor 812 on the layer 832. The conductive plane 844 is formed of a conductive material configured to provide thermal conductivity with the conductive terminal 804. The conductive material can include, but is not limited to, copper, tin, gold or other materials or alloys. The data processing circuit may be electrically connected to the conductive terminal via the conductive plane. Thus, the conductive plane 844 may be leveraged also as a thermal conductor for the temperature sensor 812 besides performing its main task of routing or establishing electrical connection of the conductive terminal 804 with other electrical components. This can save space and costs. This can also simplify the production process, e.g., assembly of the energy module 300. By preventing leaded temperature sensor, deformed sensor leads can be avoided in production. This can enhance production yield of assembled modules. By avoiding placing the temperature sensors between the cells, the module 104 can be made more compact.

The substrate layer 830 is formed of a material configured to provide thermal conductivity and electrical isolation between conductive connection 810 and temperature sensor 812 and between conductive plane 844 and temperature sensor 812. The temperature sensor 812 is disposed on the circuit board 802 at a location that provides a gap 850 between itself and the connection member 808 of the conductive terminal 804. The size of gap 850 is selected to ensure that the temperature sensor is electrically isolated from the conductive connection 810. Thus, the structure can allow a good thermal contact to the temperature sensor 812 despite being electrically isolated from the conductive terminal 804.

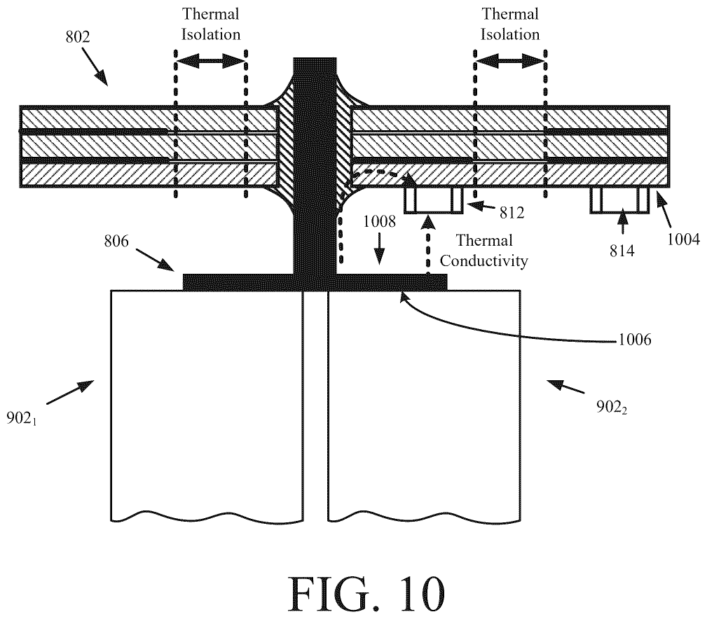

In FIG. 8, area 860 includes the conductive connection 810 and the temperature sensor 812. Area 860 is thermally isolated from other electrical components of circuit 800. The other electrical components include conductors 840, 842, 846, 848 and electronic component(s) 814. A gap 852 is provided between area 860 and components 814, 846, 848. The size and shape of gap 852 is selected so that area 860 is located at least a given distance D1 from a closest edge 862 of each conductor 846, 848. A gap 856 is also provided between area 860 and conductors 840, 842. The size and shape of gap 856 is selected so that area 860 is located at least a given distance D2 from a closest edge 864 of each conductor 840, 842. Distances D1 and D2 are selected to ensure that there is a minimized amount of thermal conductivity between area 860 and components 814, 840, 842, 846, 848 of circuit 800. An illustration is provided in FIG. 10 which shows the areas of thermal isolation and conductivity of circuit 800.

As seen in FIG. 10, the temperature sensor 812 is mounted on the surface 1004 of the circuit board 802 facing the electrical energy storage cells 902₁, 902₂. The temperature sensor 812 may be configured to output a signal comprising a value corresponding to a measured temperature of the electrical energy storage cells 902₁, 902₂.

A thermal conductivity from the temperature sensor 812 to the electrical energy storage cells 902₁, 902₂ is greater than a thermal conductivity from the temperature sensor 812 to other temperature sources (e.g., 814, 840, 842, 844, 846 and/or 848) disposed on the circuit board 802. The other temperature sources may optionally comprise a processing circuit disposed on the circuit board. The processing circuit can include, but is not limited to, electronic component(s) such as resistor(s), capacitor(s), inductor(s), amplifier(s), filter(s), selective circuit interrupt(s), voltage regulator(s), isolator(s), processor(s), gate driver(s), and/or a transistor active bridge circuit(s).

Heat is allowed to flow from the electrical energy storage cells 902₁, 902₂ to a first surface 1006 of a distal end 806 of the electrically conductive terminal 804, and from an opposing second surface 1008 of the distal end 806 of the electrically conductive terminal 804 through the air to the temperature sensor 812. The first surface 1006 of the distal end 806 being adjacent to and in contact with the electrical energy storage cells 902₁, 902₂. The second surface 1008 of the distal end 806 facing and being spaced apart from the temperature sensor 812.

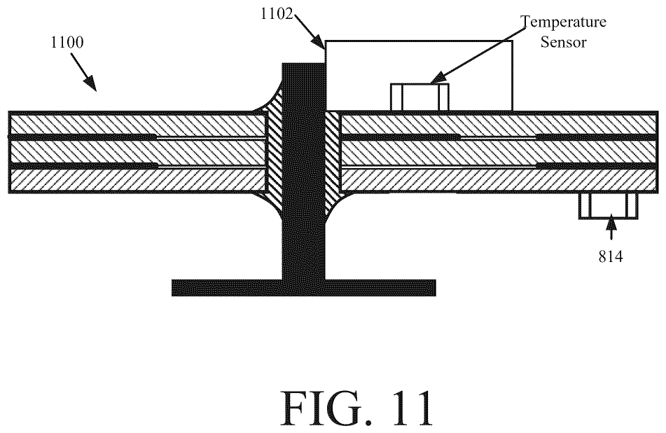

The present solution is not limited to the architecture shown in FIGS. 8-10. The temperature sensor could alternatively reside on the opposite side 1100 of the circuit board which faces away from the electrical energy storage cells as shown in FIG. 11. This alternative placement of the temperature sensor enables accessibility thereto after soldering a distal end of the conductive terminal to the circuit board. After soldering the distal end of the conductive terminal to the circuit board, the temperature sensor and the conductive connection could be thermally connected and still electrically isolated by any suitable material 1102. This material 1102 can include, but is not limited to, a potting material, thermal glue and/or thermal paste.

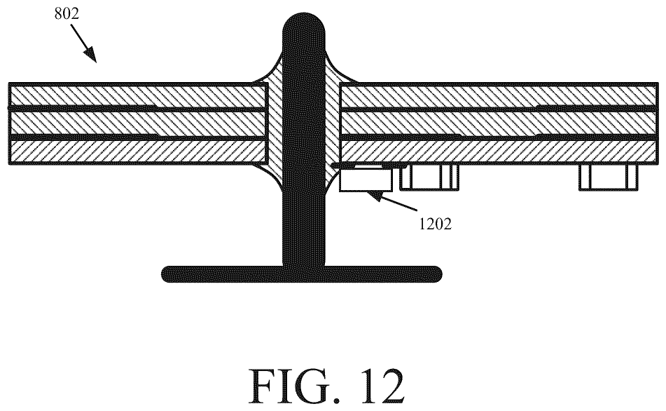

Alternatively or additionally, the thermal conductivity from the conductive connection 810 to the temperature sensor may be improved using one or more electrically isolating and thermally conductive member as shown in FIG. 12. The electrically isolating and thermally conductive member(s) 1202 can include, but are not limited to, a thermal jumper, thermal paste, thermal glue and/or a thermal potting material. Member 1202 can be connected between the conductive connection 810 and/or the temperature sensor. Any known or to be known electrically isolating and thermally conductive member can be used here.

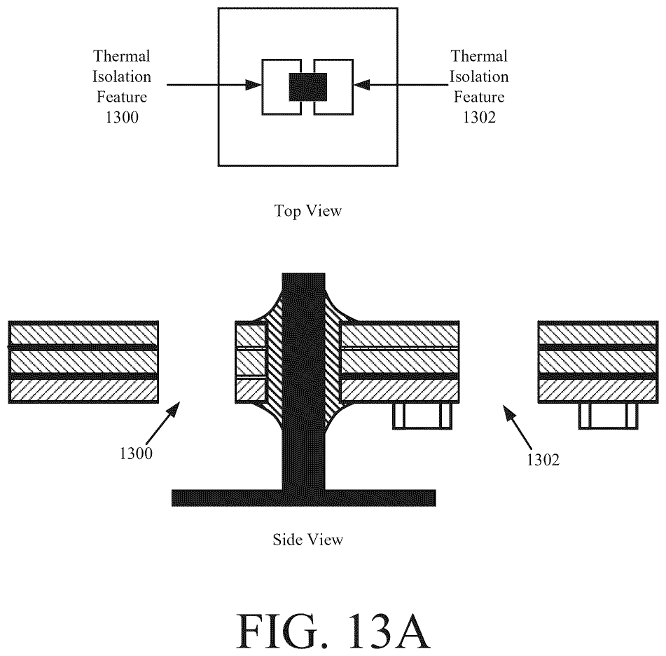

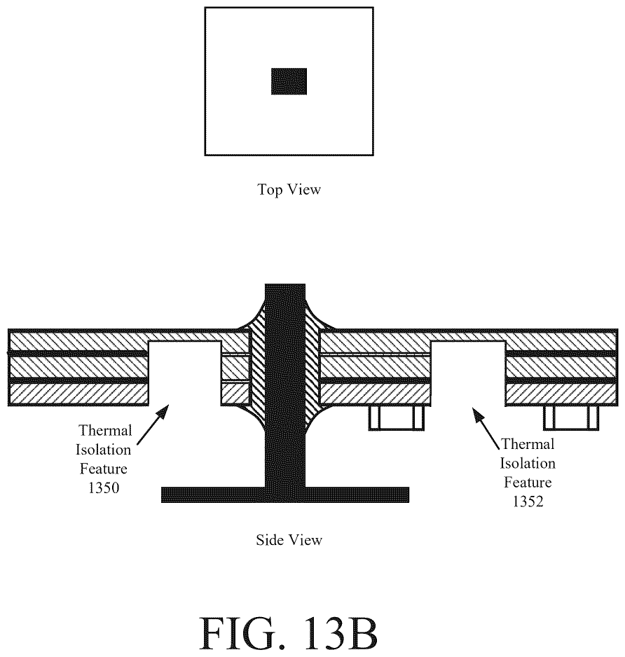

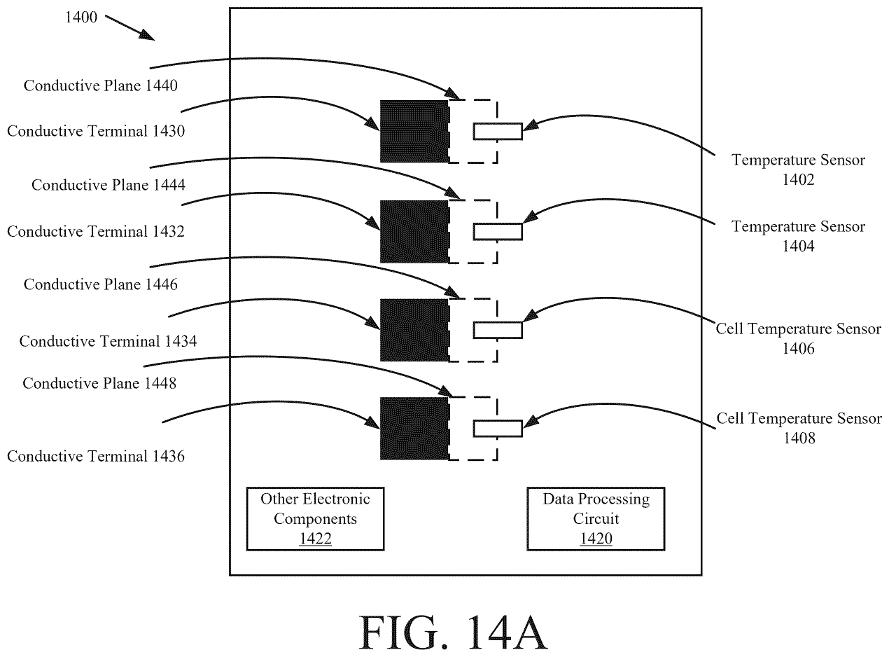

Alternatively or additionally, the circuit board can be milled or otherwise processed so that thermal isolation features are formed as voids therein to provide thermal isolation between area 860 and conductors 840, 842, 846, 848. The thermal isolation features 1300, 1302, 1350, 1352 can extend all the way through the circuit board as shown in FIG. 13A or extend only partially through the circuit board as shown in FIG. 13B.

As noted above, the energy module may comprise a plurality of conductive terminals and a plurality of temperature sensors. An illustrative architecture of this multi-sensor configuration is provided in FIG. 14. FIG. 14A shows a top view of a circuit board 1400 of an energy module that is useful for understanding the relative positions of conductive terminals 1430-1436, temperature sensors 1402-1408, and optional internal conductive planes 1440-1448. Conductive terminals 1430-1436 can include, but are not limited to, conductive terminals 404, 406, 408 of FIG. 4 and/or conductive terminal 804 of FIG. 8. Temperature sensors 1402-1408 can include, but are not limited to, temperature sensors 508 of FIG. 5 and/or temperature sensor 812 of FIG. 8. Conductive planes 1440-1448 can include, but are not limited to, conductive plane 844 of FIG. 8. FIG. 14B shows the electrical connections of the circuit board 1400.

Blocks 1420, 1422 are also provided in FIGS. 14A-14B for the data processing circuit and other electronic components. The data processing circuit 1420 can include, but is not limited to, data processing circuit 502 of FIG. 5. The other electronic components 1422 can include, but are not limited to, the module temperature sensor 518 of FIG. 5, the selective circuit interrupt 570 of FIG. 5, the voltage regulator 542 of FIG. 5, gate driver 504 of FIG. 5, isolator(s) 540 of FIG. 5, and/or transistor active bridge circuit 550 of FIG. 5.

FIG. 14B shows the electrical connections between the sensors 1402-1408, 1430-1436 and a data processing circuit 1420. As can be seen, the conductive terminals 1430, 1432, 1434, 1436 have their own electrical connection lines 1440-1446 to respective voltage measurement channels of the data processing circuit 1420. The electrical connection lines 1440-1446 can be implemented as conductors disposed on the same or different substrate layer of the circuit board 1400. The data processing circuit 1420 can be configured to compare a cell voltage measurement value received from each of the conductive terminals to a pre-specified reference value. This comparison operation is performed separately for each of the conductive terminals. As such, a voltage measurement value from conductive terminals 1430 may be compared to the reference value prior to, subsequent to and/or at the same time as a voltage measurement value from another conductive terminal 1432, 1434 or 1436 is compared to the same or different reference value.

In contrast, the temperature sensors 1402-1408 are connected to a single temperature measurement channel of the data processing circuit 1420 using a common electrical connection line 1450. Electrical connection line 1450 can be implemented as conductors (e.g., traces) disposed on the same or different substrate layer of the circuit board.

The present solution will now be explained with the following examples to show ways to reduce measurement channels needed for temperature monitoring of multiple spots or regions of a circuit. In general, the present solution involves arranging a plurality of temperature sensors in such an electrical network that electrical response of the electrical network is not only dependent on the overall behavior of the sensors, but it is dominatable by any one or more of the temperature sensors when those sensors experience larger than nominal temperature variation (e.g., as compared to nominal or acceptable temperature range) than the rest of the sensors. For example, the present solution can be applied to any impedance-based temperature sensors for measuring overtemperature or under-temperature. The following examples are shown with thermistor type sensors in which electrical resistance of the sensor is temperature dependent. It shall be appreciated that other kinds of sensors can also be applied. The present solution can also open several different applications and goals, for example, by employing one or more sensors having higher temperature sensitivity as compared to the others. By doing so, when they are arranged in an electrical network as mentioned above, they can dominate the electrical response of the electrical network with smaller changes in their temperature. This can allow assigning higher temperature sensitivity to certain regions of the circuit (e.g., where these higher temperature sensitivity one or more sensors are provided) as compared to other regions (e.g., where these lower temperature sensitivity sensors are provided). Additionally, or alternatively, sensors with different impedance values (e.g., resistance) can be selected for different regions in order to assign different priority (e.g., measurement weightage or bias) to different regions. These features can be achieved by a single measurement channel (e.g., by measuring at the measurement tap), thereby being particularly suitable for compact applications and/or low-cost applications (e.g., portable power units). The examples below will mostly refer to overtemperature measurements. However, equivalent circuits for under-temperature monitoring can also be realized by arranging given types of sensors in such a network that electrical response of the electrical network is not only dependent on the overall behavior of the sensors, but it is dominatable by any one or more of the temperature sensors when those sensors experience larger magnitude of under-temperature. Certain examples of the networks will be provided for overtemperature monitoring, but those networks are also usable for under-temperature monitoring with a sensor behavior (e.g., temperature coefficient) which makes the sensor dominant in defining electrical response of the electrical network for the temperatures in which the monitoring should trigger.

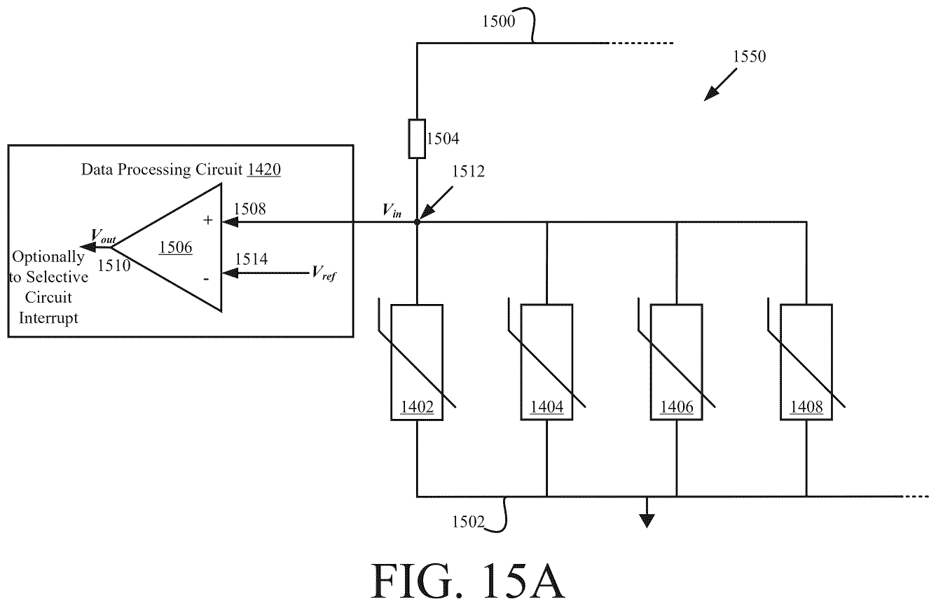

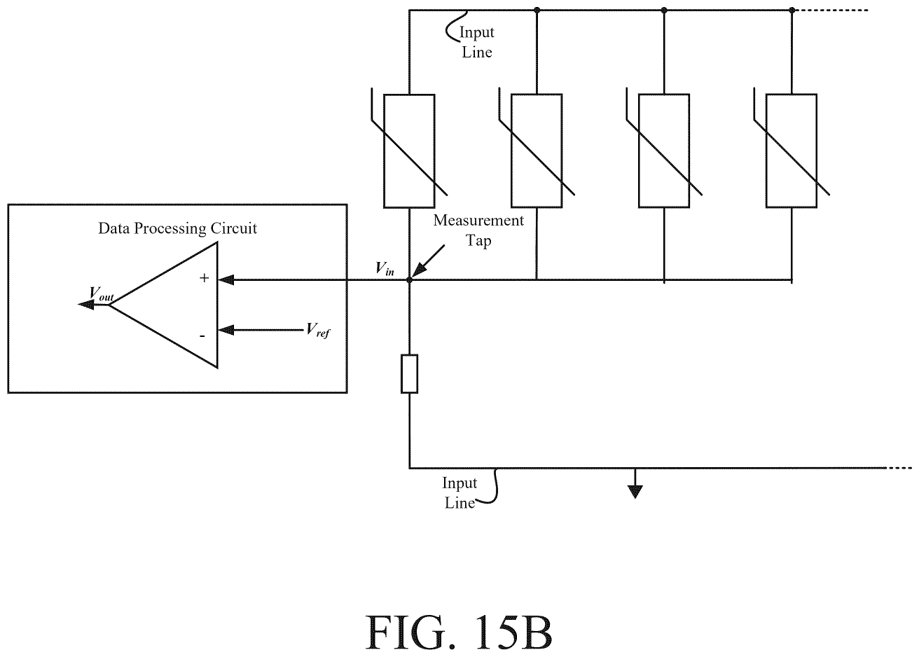

FIG. 15A provides a more detailed circuit diagram 1550 that is useful for understanding the manner in which the cell temperature monitoring is achieved using the temperature sensors 1402-1408 and data processing circuit configuration 1420. In this example, the electrical network comprises a parallel arrangement (e.g., parallelly connected) of temperature sensors 1402-1408, shown here as thermistors.

As shown in FIG. 15A, the temperature sensors 1402-1408 comprise surface mount thermistors that are connected in parallel between a measurement tap 1512 and a reference potential 1502. Each thermistor comprises an electrical resistor whose resistance is variable depending on its temperature. For example, the resistance of the thermistor is reduced when the temperature of the electrical resistor increases and is increased when the temperature of the electrical resistor is decreased. It shall be appreciated that a temperature sensor exhibiting such a behavior can be said to have a negative temperature coefficient (NTC). It shall also be appreciated that the present solution is not limited to thermistors, rather any kind of NTC temperature sensor can be applied in the configuration such as the one shown in FIG. 15A.

A resistor 1504 is provided to facilitate measuring an electrical signal (Vᵢₙ) at the measurement tap 1512. The resistor 1504 is connected between the measurement tap 1512 and a DC voltage supply or input line 1500. In this way, a voltage divider configuration is provided by the resistor 1504 and the parallelly connected thermistors 1402-1408 between input lines 1500, 1502. The thermistors 1402-1408 in this example are sharing a voltage, i.e., voltage (Vᵢₙ) at the measurement tap 1512. Each thermistor is provided to monitor different physical temperature measurement spots of an energy module. In this voltage divider configuration, the temperature of each thermistor may be unable to be determined because for each voltage value at measurement tap 1512 there may be several combinations of thermistor temperatures associated therewith. For example, the measurement tap has a voltage value when a temperature of thermistor 1402 is higher than all other thermistors 1404-1408, and has the same voltage value when temperatures of thermistors 1404, 1408 are higher than all other thermistors 1402, 1406. The measurement tap can also have the same voltage value when the temperate of thermistor 1402 equals the temperature of all other thermistors 1404-1408. The present solution is not limited to the particulars of this example. However, knowing the exact temperature of each thermistor may not be necessary for detecting when a certain temperature limit of one or more temperature measurement points is exceeded.

Accordingly, the arrangement 1550 can still be used for detecting overtemperature condition at any one or more measurement spots. For example, if temperature is increasing at all thermistors 1402-1408, the effective resistance of the parallel arrangement will decrease, thereby causing the electrical signal Vᵢₙ at the measurement tap 1512 to change. This change can be evaluated, for example, via the data processing circuit 1420 to determine an occurrence of a temperature error (e.g., an overtemperature condition). As another example, assuming that the thermistor 1408 is experiencing higher temperature as compared to the rest of the thermistors 1402-1406, the effective resistance of the parallel arrangement will also decrease, thereby causing the electrical signal Vᵢₙ at the measurement tap 1512 to change. Also, at one point, the effective resistance of the parallel arrangement will become dominant by resistance value of the thermistor 1408, thereby allowing determination of an occurrence of a temperature error (e.g., an overtemperature condition) even in local overheating conditions. This can be shown by an example of two resistances R1 and R2 connected in parallel. The effective resistance of the network with parallelly connected R1 and R2 will be (R1·R2)/(R1+R2). Assuming that R1<<R2, the effective resistance approaches (R1·R2)/(R2)≈R1. A similar behavior can be observed when there are more than two resistances (e.g., resistive temperature sensors) connected in parallel. The present solution thus leverages arranging a plurality of temperature sensors in such an electrical network that electrical response of the electrical network is not only dependent on the overall behavior of the sensors, but it is dominatable by any one or more of the temperature sensors when those sensors experience higher temperature than the rest of the sensors (or lower depending on the configuration). As can be seen with the above non-limiting example, a thermistor having resistance R1 which is significantly lower than the rest (e.g., due to local overheating) would dominate the effective resistance of parallelly connected thermistors, thus allowing the network to be responsive to a temperature error. It shall be appreciated that such network can allow detection if any one or more sensors are experiencing overtemperature (or under temperature depending on the configuration).

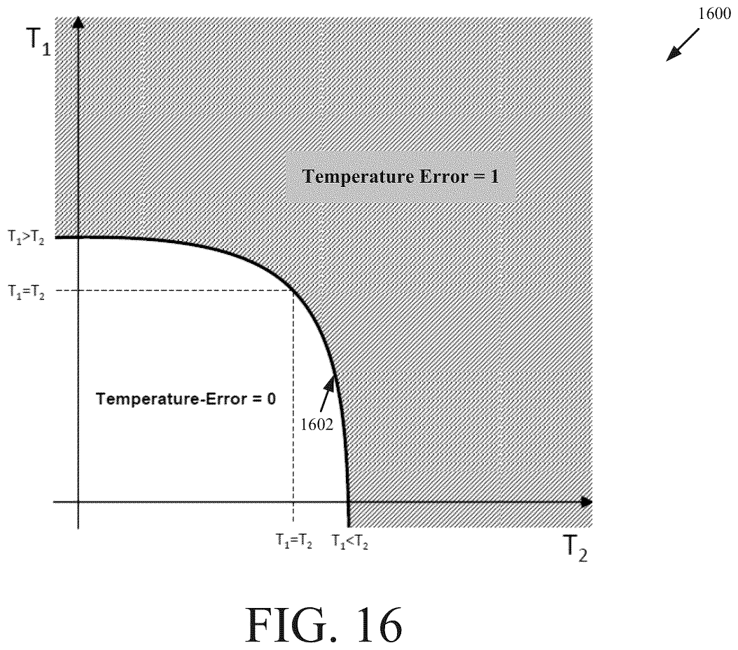

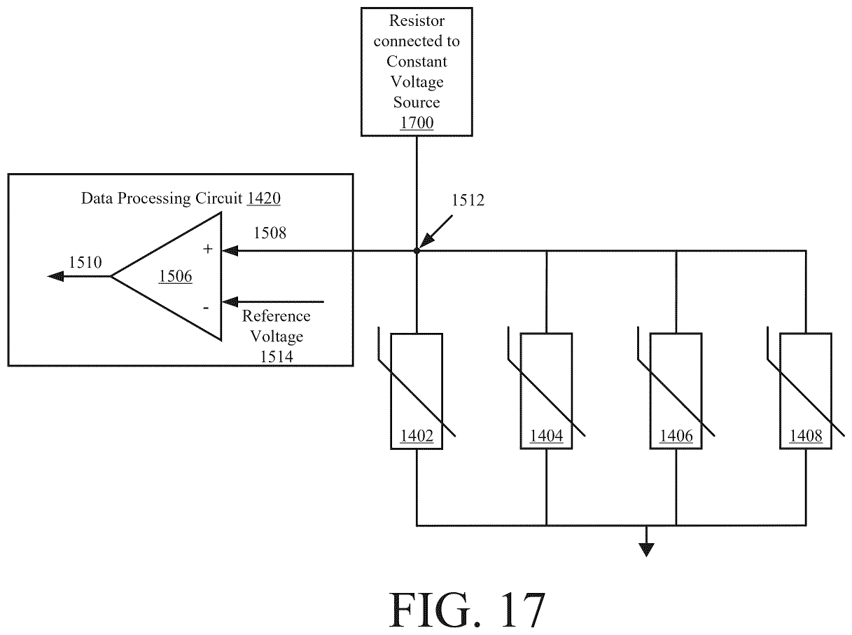

A graph 1600 is provided in FIG. 16 that shows a non-limiting qualitative correlation between two temperatures T1, T2 represented by two parallel NTC thermistors, e.g., 1402, 1404 and a fixed threshold temperature value represented by curve 1602. FIG. 16 covers a scenario of two parallel NTC sensors (e.g., thermistors) monitored for overtemperature threshold. Graph 1600 shows that even if only one temperature is rising while the other temperature stays significantly lower (e.g., T1>T2 or T2>T1), a temperature error is triggered reliably at a certain adjustable temperature limit. This is because of the lower resistance thermistor dominates in the parallel circuit architecture. Accordingly, in a single electrical energy storage cell failure event, the temperature error is reliably triggered by the data processing circuit 1420 at a certain selected single cell temperature, although the rest of the electrical energy storage cells stay at a comparably low temperature. The temperature limit for the scenario in which all electrical energy storage cells of an energy module have the same temperature is lower as for the single electrical energy storage cell temperature limit. This means that when adjusting the circuit parameters a compromise between single temperature limit and combined temperature limit can be made. The reference voltage 1514 of FIG. 15A can be selected accordingly.

In the non-limiting example shown in FIG. 15A, the data processing circuit 1420 comprises a comparator 1506 with two input terminals 1508, 1514. The voltage Vᵢₙ at measurement tap 1512 is provided to input terminal 1508 and a reference voltage V_{ref} is provided at input terminal 1514. If voltage Vᵢₙ is less than the V_{ref}, then the signal state at output terminal 1510 of the comparator is low. In contrast, if voltage Vᵢₙ is greater than the reference voltage V_{ref}, then the signal state at Vₒᵤₜ at the output terminal 1510 of the comparator is relatively high. The high valued output Vₒᵤₜ can, for example, cause a selective circuit interrupt (e.g., selective circuit interrupt 570 of FIG. 5) to transition from a closed state to an open state, whereby the energy flow from the energy storage cells to the input line 510 and active bridge 550 is interrupted. As long as the low signal state at output 1510 exists, the selective circuit interrupt remains in its closed state in which the energy flow from the energy storage cells to the input line 510 and the active bridge 550 is not interrupted. Thus, the selective circuit interrupt can be considered as being normally in a closed state. It shall be appreciated that the data processing circuit 1420 type shown in this example is non-essential and non-limiting to the present teachings. Hence, any other suitable circuit realized in hardware and/or software may be used. As certain non-limiting examples include, ADC, a software module which compares the measured value against a limit, their likes and/or their combinations.

The circuit architecture of FIG. 15A may be used, for example, with negative temperature coefficient (NTC) sensors for overheat detection. This is because the hottest temperature sensor will have the lowest resistance which will dominate the network, and hence lead towards the threshold. If all or most of the temperature sensors are increasing in temperature together, there will be a similar outcome. In other words, the objective is to have the battery module enter a safe mode if there is either local overheating (e.g., one sensor is hot) or the whole energy module is hot.

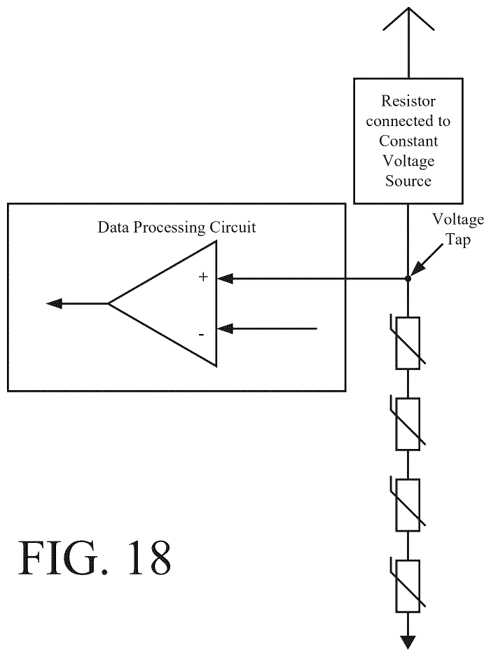

The present solution is not limited to the particulars of FIG. 15A. For example, as shown in FIG. 15B, the locations of the resistor and temperature sensors can be switched in relation to the two input lines. Alternatively, the resistor 1504 may be replaced with a constant current source 1700 as shown in FIG. 17. Additionally or alternatively, the temperature sensors could be coupled in series rather than in parallel to the measurement tap as shown in FIG. 18. In the series configuration, the collective resistance is dominated by the highest resistance. Thus, if positive temperature coefficient (PTC) sensors are used in series, local overheating could be detected by a given temperature sensor with high resistance, and module overheating can be detected as the resistance of all or most of the temperature sensors increase-hence increasing the total series resistance as well. A series network with PTC sensors is thus another example of the network which can allow detection when any one or more sensors are experiencing overtemperature. It shall be appreciated that the block located on the upper side of the “Voltage Tap”, i.e., the block called “Resistor connected to Constant Voltage Source” as shown in FIG. 18 in some non-limiting embodiments may be replaced by a current source. Similarly, in some non-limiting embodiments, the temperature sensors coupled in series may be located on the upper side of the voltage tap, while the resistor may be located on the lower side of the voltage tap. Similarly, in some non-limiting embodiments, such the lower side resistor may be replaced by a current sink which draws current from the voltage tap towards a lower potential (e.g., ground potential). Hence, more generally, the sensor position and the resistor/current source/sink position may be flipped in certain embodiments without limiting the scope and generality of the present teachings. Furthermore, the polarity of inputs of comparator (e.g., comparator 1506) shown in any of the Figures herein disclosed is non-limiting to the generality or scope of the present teachings. It shall be appreciated that the polarity may be opposite in some non-limiting embodiments. For example, FIG. 17 shows the tap 1512 coupled to “+” input of comparator 1506, while reference voltage 1514 is connected to “−” input of comparator 1506. It shall be appreciated that the tap 1512 is coupled to “−” input of comparator 1506, while reference voltage 1514 is connected to “+” input of comparator 1506, without departing from the present teachings. This may cause a change in output polarity of the comparator 1506. However, this can still be utilized for the purposes of the present teachings as herein disclosed.

It should be noted that an overtemperature (higher temperatures dominate) may be monitored by NTC sensors in parallel or PTC sensors in series. An undertemperature (lower temperatures dominate) may be monitored by NTC sensors in series and PTC sensors in parallel. Other types of temperature sensing elements can be used such as platin sensors. Additionally, or alternatively, sensors with different resistance values and/or sensitivities can be used for different spots so as to achieve different monitoring priority and/or sensitivity for those spots. For example, any sensor may be provided a lower nominal resistance value in a parallel network such that it is more dominant than the rest, and/or any sensor may be provided with a larger negative temperature coefficient than the rest such that temperature changes become more dominant with a smaller change in the temperature. Similarly, in other kinds of networks too, different weightage and/or sensitivities can be achieved by selecting sensor characteristics accordingly which cause certain sensors to dominate the network response.

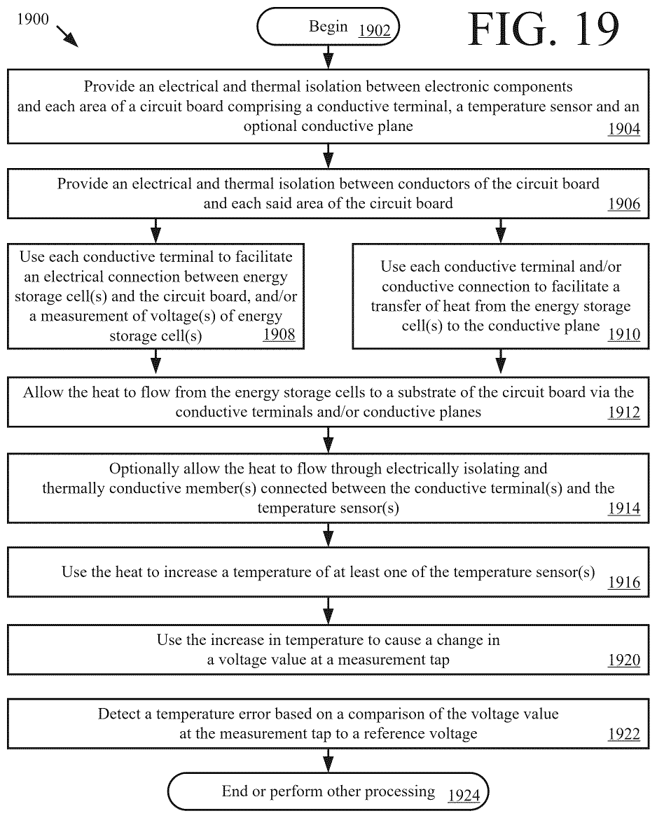

FIG. 19 provides a flow diagram of an illustrative method 1900 for operating an energy module. The operations of blocks of FIG. 19 can occur in a different order than that shown. Method 1900 can additionally or alternatively include more or less blocks than that shown.

Method 1900 begins with 1902 and continues with 1904 where an electrical and thermal isolation is provided between electronic component(s) of the circuit (e.g., component(s) 814 of FIG. 8) and an area (e.g., area 860 of FIG. 8) of a circuit board (e.g., circuit board 802 of FIG. 8) comprising a conductive terminal (e.g., conductive terminal 804 of FIG. 8), a temperature sensor (e.g., temperature sensor 812 of FIG. 8) and an optional conductive plane (e.g., conductive plane 844 of FIG. 8). The thermal isolation is provided by one or more gaps (e.g., gaps 852, 856 of FIG. 8, thermal isolation features 1300, 1302 of FIG. 13A, and/or thermal isolation features 1350, 1352 of FIG. 13) located on and within the circuit board between the other electronic components and the area. The gap(s) is (are) filled with a gas (e.g., air) or a portion of at least one material forming the circuit board or any other material providing thermal isolation. An electrical and thermal isolation is also provided in 1906 between conductors (e.g., conductors 840, 842, 846, 848 of FIG. 8) of the circuit board and the area of the circuit board comprising the conductive terminals, the temperature sensor and/or the conductive plane.

In 1908, the conductive terminal is used to facilitate (i) an electrical connection between energy storage cell(s) and the circuit board and/or (ii) a measurement of voltage(s) of electrical energy storage cell(s) (e.g., electrical energy storage cell 902₁ and/or 902₂ of FIG. 9). As such, the conductive terminal is electrically connected to a data processing circuit (e.g., data processing circuit 502 of FIG. 5) so that the voltage measurement can be analyzed to detect when the electrical energy storage cell(s) are not operating as expected such as when the cell voltage falls outside an acceptable range of voltage values. This electrical connection between the conductive terminal and the data processing circuit may be made using a conductor or a conductive plane disposed on a substrate layer of the circuit board.

The conductive terminal is also used in 1910 to facilitate a transfer of heat from the electrical energy storage cell(s) to the conductive plane provided within the circuit board. 1910 may also optionally involve using a conductive connection, provided between the conductive terminal and the circuit board, to further facilitate the transfer of heat from the electrical energy storage cell to the conductive plane.

In 1912, heat is allowed to flow from the electrical energy storage cell to a substrate (e.g., substrate layer 830 of FIG. 8) of the circuit board via the conductive terminal, conductive connection and/or the conductive plane. The heat may also optionally be allowed to flow in 1914 through an electrically isolating and thermally conductive member (e.g., electrically isolating and thermally conductive member 1202 of FIG. 12) that is connected between the conductive connection and the temperature sensor.

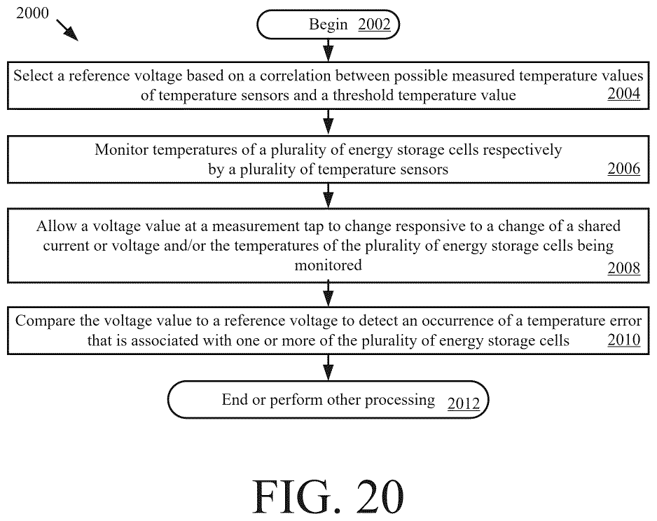

In 1916, the heat is used to increase a temperature of the temperature sensors(s). The increase in temperature is used in 1918 to cause a change in a voltage value at a measurement tap. The measurement tap can include, but is not limited to, a voltage tap of a voltage divider (e.g., voltage divider 1550 of FIG. 15) disposed on the circuit board. A temperature error is detected in 1922 based on a comparison of the voltage value (e.g., voltage Vᵢₙ of FIG. 15) at the measurement tap to a reference voltage (e.g., voltage V_{ref} of FIG. 15). Subsequently, method 1900 continues to block 1924 where it ends or other operations are performed. The other operations can include, but are not limited to, returning to block 1902 or continue to block 2002 of FIG. 20.

FIG. 20 provides a flow diagram of another illustrative method 2000 for operating an energy module (e.g., energy module 300 of FIGS. 3-4). The operations of blocks 2002-2012 can occur in a different order than that shown. Method 2000 can additionally or alternatively comprise more or less blocks than that shown.

Method 2000 begins with 2002 and continues with 2004 where a reference voltage (e.g., V_{ref} of FIG. 15) is selected based on a correlation between possible measured temperature values of a plurality of temperature sensors and a threshold temperature value.

In 2006, temperatures of a plurality of electrical energy storage cells (e.g., electrical energy storage cells 400 of FIGS. 4-5, and/or electrical energy storage cells 902₁, 902₂ of FIGS. 9-10) are monitored respectively by the temperature sensors (e.g., temperature sensors 508 of FIG. 5, temperature sensor 812 of FIG. 8, and/or temperature sensors 1402-1408 of FIG. 14). The temperature sensors may include thermistors. The temperature sensors are arranged in a network such that each temperature sensor shares a current or voltage with at least another temperature sensor. This arrangement can include, but is not limited to, a parallel arrangement of the temperature sensors or a series arrangement of the temperature sensors. The shared current or voltage may be measurable at a common measurement tap of the circuit. The temperature sensors may be mounted to a surface of a circuit board (e.g., circuit board 802 of FIGS. 8 and/or 1400 of FIG. 14) that is (i) internal to the energy module and (ii) spaced apart from the energy storage cells. In 2006, heat may be allowed to flow from the electrical energy storage cell(s) to a substrate (e.g., substrate layer 830 of FIG. 8) of the circuit board, for example, via an optional conductive terminal(s) (e.g., conductive terminal 804 of FIG. 8). This heat may be used to increase a temperature of one or more temperature sensors. Notably, the substrate may be used in block 2006 to electrically isolate the respective temperature sensor from the conductive terminal.

Responsive to a change of the shared current or voltage and/or the monitored temperatures of the electrical energy storage cells, a voltage value at a measurement tap (e.g., measurement tap 1512 of FIG. 15) is allowed to change in block 2008. The change in the shared current or voltage may be caused by the temperatures of the electrical energy storage cells being monitored. The measurement tap can include, but is not limited to, a voltage tap of a voltage divider (e.g., voltage divider 1550 of FIG. 15). For example, the increase in the temperature of the temperature sensor(s) causes the change in the voltage value at the measurement tap. The voltage divider may comprise (1) a resistor (e.g., resistor 1504 of FIG. 15) connected between a first input line (e.g., input line 1500 of FIG. 15) and the measurement tap and (2) the plurality of temperature sensors connected in series or parallel between the measurement tap and a second input line (e.g., input line 1502 of FIG. 15). The first or second input lines may be connected to ground. The present solution is not limited to the particulars of this example.

Block 2010 can involve comparing the voltage value to a reference voltage to detect an occurrence of a temperature error that is associated with the energy module and/or one or more of the plurality of energy storage cells. It should be noted here that the voltage value represents or otherwise indicates a combined temperature of the energy storage cells rather than a temperature of a single energy storage cell. Subsequently, method 2000 continues to block 2012 where it ends or other operations are performed (e.g., return to 2002 or perform method 1900 of FIG. 19).

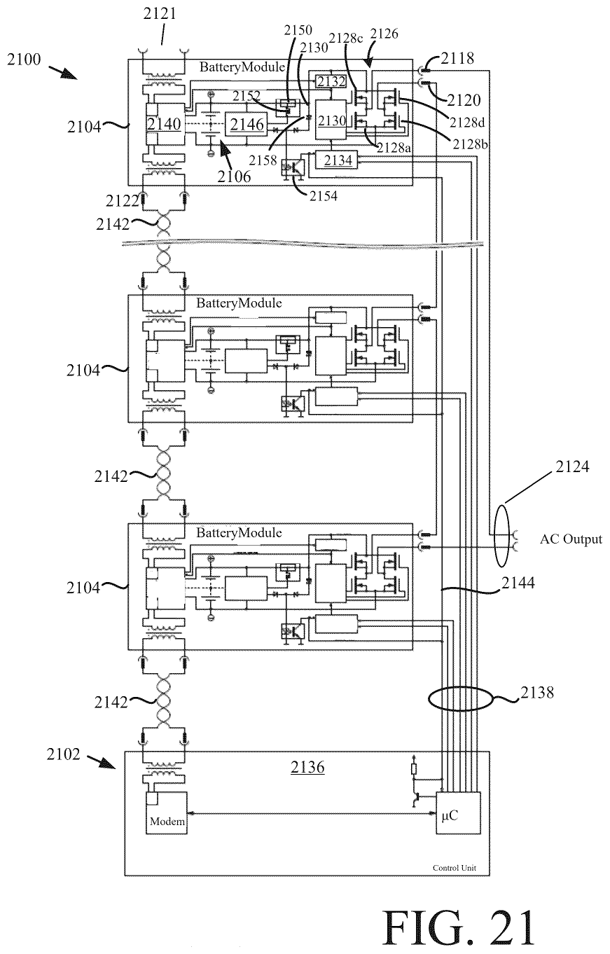

FIG. 21 provides a block diagram of an electrical power system 2100, which may be in the form of an electrical power unit (which may e.g., be power supply 100 as shown in FIGS. 1, 2). Electrical power system 2100 includes at least one energy module 2104 (which may e.g., be module 104), shown in this non-limiting example as a plurality of energy modules 2104, which in a non-limiting manner may also be called battery modules or energy storage modules. Electrical power unit or system 2100 may also comprise a control unit 2136 which may control operation of the at least one module 2104. Control unit 2136 may e.g., be controller 200 as discussed in previous FIGS., or control unit 2136 may comprise controller 200. In this example, the control unit 2136 is shown comprising a modem 2102 for communicating (unidirectional or bidirectional) with the modules 2014. In this example, the control unit 2136 is also shown comprising a microcontroller (“μC”). The control unit 2136 may either be external to the electrical power unit 2100, or it may at least partially be a part of the electrical power unit 2100.

The electrical power unit 2100 comprises several battery modules 2104, wherein only three modules are shown in FIG. 21. Each of the battery modules 2104 comprises one or more energy storage cells 2106 (which may e.g., be cells 400, 602). The at least one energy module 2104 comprises a power port (e.g., power out interface 310) with terminals 2118 and 2120 (which may e.g., be terminals 560 and 562), via which electrical energy may be received (e.g., input) for charging the energy storage cells 2106 in a charge mode. Additionally, or alternatively, electrical energy stored in the energy storage cells 2106 may be supplied (e.g., output) via the same port or terminals 2118 and 2120, or via another port, in a discharge mode. The terminals 2118 and 2120 of a power port may also be called power terminals of that respective module 2104, (e.g. first power terminal 2118 and second power terminal 2120).

The energy storage cells 2106 are connectable to the power port (e.g., via terminals 2118 and 2120 of their respective module 2104) for providing electrical power at a power bus 2124, which may deliver power (e.g., AC output and/or DC output) to an electrical load (not shown in FIG. 21). It shall be appreciated that power bus 2124 may correspond to wires 106, 108 as shown in FIG. 1. The same power bus 2124 may be used for charging the energy storage cells 2106. Thus, module 2104 comprises a power bus 2124 which facilitates flow of electrical energy between one or more energy storage cells 2106 and a power port (e.g., one or more power terminals 2118, 2120) of that module 2104. For example, electrical energy may flow from the energy storage cells 2106 towards the power port during a discharge phase, while electrical energy may flow from the power port towards (e.g., into) the energy storage cells 2106 during a charge phase. Energy module 2104 comprises a disabling device 2152, which in this non-limiting example is shown provided in the positive circuit between the cells 2106 and switching circuit 2126 (which may e.g., be active bridge 550). It shall be appreciated that the disabling device 2152 may also be termed a disconnecting means.

In some non-limiting aspects, each module 2104 may further comprise the switching device 2126. In this example, the switching device 2126 comprises four electrical switch elements 2128a-d (e.g., MOSFETs, which may or may not be devices 520, 522, 524 and 526), for selectively connecting the energy storage cells 2106 to the power port terminals 2118 and 2120 of the corresponding module 2104. The electrical switch elements 2128a-d are shown here interconnected in the form of an H-bridge circuit, more specifically a full H-bridge. It shall be appreciated that the switching device 2126 may be in any other form, for example, a half H-bridge, or any other arrangement which allow selectably either connecting or disconnecting the energy storage cells 2106 to an output port of that module (e.g., the power port terminals 2118 and 2120 of module 2104 shown in this non-limiting example). In some non-limiting embodiments, the switching device 2126 may even allow selectably connecting one, some, or all of the energy storage cells 2106 to the output port. Thus, it may even be allowed to disconnect certain cells (e.g., defective or discharged ones) from delivering power at the output port, while providing power from other of the energy storage cells 2106 (e.g., which are healthy).

In order to operate the switching device 2126 each module 2104 may have an isolated gate driver circuit 2130 which is supplied by a voltage regulator 2132. The isolated gate driver 2130 is connected to a control circuit 2134 shown in this non-limiting example as PWM decoder. The control circuit 2134 is operable to generate a switching signal for the isolated gate driver 2130. The gate driver circuit 2130 uses the switching signal to operate the respective switches 2128a-d of the switching device 2126. In some cases, the PWM decoder 2134 may simply decode an instruction signal from a control unit 2136.

The switching device 2126 is provided between the power port terminals 2118 and 2120 of the module 2104 and is operable to provide different connection states at the power port. These may be, a first polarity state in which the energy storage cells 2106 of that module are connected to the power port terminals 2118 and 2120 in a first polarity (e.g., a +polarity), a second polarity state in which the energy storage cells 2106 are connected to the power port terminals 2118 and 2120 in a second polarity which is opposite of the first polarity (e.g., a −polarity), a bypass stage in which the lower two of the electrical switch elements 2128a, 2128b (the MOSFETs connected to the low-polarity terminal (e.g., −line 2212) of the energy storage cells 2106) are switched ON and in which the upper two of the electrical switch elements 2128c, 2128d (the MOSFETS connected to the high-polarity terminal (e.g., +line 2210) of the energy storage cells 2106) are switched OFF, and a Hi-Z state in which all four of the electrical switch elements 2128a-d are switched OFF. It shall be appreciated that lines 2210 and 2212 may correspond lines 510 and 512 respectively, e.g., as shown in FIG. 5.

It shall be appreciated that in the bypass mode of a module 2104, a current flow between the energy storage cells 2106 and the power port terminals 2118, 2120 of that module is prevented, however current may still flow between the terminals 2118 and 2120 of that power port. In some non-limiting aspects, the switching device 2126 may also be termed a disconnecting means via which the energy storage cells 2106 can be disconnected from the power port of a specific module 2104 (e.g., terminals 2018 and 2020 of that module). It shall be appreciated, e.g., bypass mode allows disconnecting or isolating the energy storage cells 2106 from the power port of that module 2104.

The electrical power unit 2100 comprises the control unit 2136. The control unit 2136 may be connected to each control circuit (e.g., PWM decoder) 2134 via a respective control channel 2138 (e.g., a digital communication bus). The electrical power unit 2100 may, for example, be in the form of an electrical power supply which is operable to provide AC and/or DC output. In some non-limiting aspects, e.g., in charge mode, the electrical power system 2100 may be operable to charge some, or all energy storage cells 2106 of one or more modules 2104. For example, module 2104 may be operable to charge at least some of the energy storage cells 2106 (e.g., by power received via its power port). Similarly, module 2104 may be operable to output AC and/or DC power at its output port (e.g., terminals 2118 and 2120 of that module 2104).

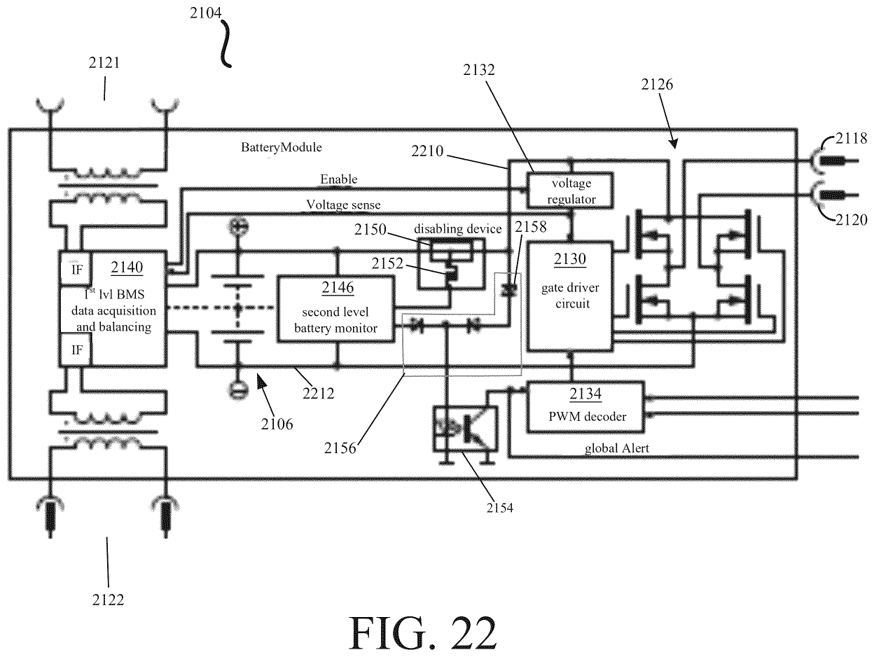

In some non-limiting aspects, at least one module 2104 comprises a first monitoring circuit 2140. In some non-limiting cases, the first monitoring circuit 2140 may also be called a first level battery management system (“BMS”). For example, the first monitoring circuit 2140 or the 1^{st} level BMS may be used for data acquisition of one or more parameters (e.g., any one or more of: current, voltage, temperature, charge, of one or more cells 2106) related to that module 2104. In this example, besides measuring temperature of each of the cells 2106, the first monitoring circuit 2140 also measures voltage (e.g., via “Voltage sense” line as shown in FIG. 22) of the voltage regulator 2132. In case an abnormal condition is detected, the first monitoring circuit 2140 may disable the module 2104, e.g., by removing “Enable” signal as shown in FIG. 22. Additionally, or alternatively, the first monitoring circuit 2140 may perform and/or monitor balancing operations such as charge balancing and/or load balancing. In the example shown in FIG. 21, each module 2104 comprises a first monitoring circuit 2140. The first monitoring circuit 2140 is operable to monitor physical parameters of each corresponding module 2104 of energy storage cells 2106. It shall be appreciated that the first monitoring circuit 2140 may be the data processing circuit 502 as was discussed e.g., in FIG. 5. With limitation, in this disclosure the terms first monitoring circuit 2140, first battery monitor circuit, and first monitor circuit may be used interchangeably.

In FIG. 21, the multiple first monitoring circuits 2140 of respective modules 2104 are connected via a communicative coupling 2142, shown here as a communication bus 2142, to the control unit 2136. The multiple first monitoring circuits 2140 are shown in this example connected in a daisy chain fashion to the control unit 2136. Each connected module 2104 may have at least one communications interface 2121 and/or 2122 for connecting to the communication bus 2142. In this example, each module 2104 is shown comprising two communications interfaces, namely, an upstream interface 2121 and a downstream interface 2122 for connecting upstream and downstream of the communication bus 2142. It shall be appreciated that the terms upstream and downstream are used without limitation merely to distinguish the two interfaces 2121 and 2122. In this example, each interface 2121 and 2122 comprises a transformer of which one winding is connected to an interface port (“IF”) of the first monitoring circuit 2140. The other winding of the transformer may be connected to the communication bus 2142.

The communication bus 2142 is disposed to transmit the physical parameters measured by the first monitoring circuit 2140 of respective module to the control unit 2136. The control unit 2136 receives these parameters via a connectivity unit 2102 (e.g., modem). The control unit 2136 may compare the acquired physical parameters to respective threshold values. If violation of either one of the threshold values is determined by the control unit 2136, the control unit 2136 is operable of performing one or several measures to set the respective module 2104 in a safe state (e.g., disable that module), of which physical parameters have been detected as exceeding. In some cases, the control unit 2136 may disable all modules 2104.

The control unit 2136 may be operable to transmit a first instruction signal over the control channel 2138 to the PWM decoder 2134 of the respective defective module 2104. The first instruction signal transmitted via the control channel 2138 is used by the respective PWM decoder 2134 to bring the switching device 2126 in a safe state (e.g., Hi-Z or bypass state), thereby disconnecting the corresponding energy storage cells 2106 from the module power port with terminals 2118, 2120. In some cases, first monitoring circuit 2140 may be operable to disable the module 2104 via a disconnecting means (e.g., the switching device 2126 of that module). An advantage of this approach can be that the same switching device 2126 which is used to provide desired output power (e.g., at the output port), can be leveraged to isolate the module 2104 (e.g., the storage cells 2106 thereof from the output port) in case of an undesired state. The switching device 2126 may also be collectively termed a first switch.

The control unit 2136 may be operable to assert a global alert line 2144, e.g., by transmitting a signal on the global alert line 2144. The global alert line 2144 may interconnect the PWM decoders 2134 of all modules 2104, and it may also be connected to the control unit 2136. E.g., upon receiving a second instruction signal via the global alert line 2144, the PWM decoders 2134 of all modules 2104 may place their switching device 2126 in a Hi-Z mode, thereby disconnecting their energy storage cells 2106 from their power port terminals 2118/2120.

The control unit 2136 may be operable to generate a third instruction signal, e.g., a “disable” signal transmitted via the communication bus 2142 to the voltage regulator 2132. The third instruction signal is used by voltage regulator 2132 to cut the power supply of the gate driver 2130 resulting in a Hi-Z state in which the module 2104 is disabled and the energy storage cells 2106 are disconnected from their respective power port terminals 2118, 2120.

To enhance safety of modules 2104 and/or cells 2106, it may be desirable to have independent safety mechanisms which can ensure safe state in case an undesired situation arises. Some non-limiting examples of such undesired states can be any one or more of: over temperature, under temperature, over voltage, under voltage, or any other even indicative of an undesired state occurring or likely occurring. Thus, pursuant to the teachings there can be provided multiple independent disabling means for isolating a specific, some, or all modules 2104 in response to an undesired state (e.g., any one or more of: a defective module, a defective storage cell 2106, unreliable or undesirable parameters, etc.).

For providing an independent safety mechanism which does not rely solely upon the first monitoring system 2140 and/or the control unit 2136 for bringing the module 2104 in a safe state, there may be provided at least one module 2104, a second monitoring circuit 2146. In the example shown in FIG. 21, each module 2104 comprises a respective second monitoring circuits 2146 to monitor certain physical parameters of that module 2104. The second monitoring circuit 2146 is operable to measure at least some of the physical parameters independently of the first monitoring circuit 2140. With limitation, in this disclosure the terms second monitoring circuit 2146, second battery monitor circuit, and second monitor circuit may be used interchangeably

The second monitoring circuit 2146 may be operable to compare the physical parameters to their respective threshold values, and in response to any of the monitored physical parameters violating their respective threshold value, the second monitoring is operable to disable the module 2104 e.g., via at least one disabling device (e.g., disabling device 2152) which is not controllable via the first monitoring circuit 2140. Thus, disabling device 2152, which may also be termed a second switch, may be a disconnecting means which is independent and/or different from the disconnecting means 2126 (or switching device 2126). As shall be appreciated, the second monitoring circuit 2146 may thus be operable to disable the module 2104 of energy storage cells 2106 via a second switch 2152 while the first monitoring circuit 2140 is operable to disable that module 2104 of energy storage cells 2106 via a first switch 2126, the first switch 2126 being different from the second switch 2152. In other words, the first monitoring circuit 2140 may be operable to disable the module 2104 via a disconnecting means 2126 (e.g., first disconnecting means 2126) which is different from a disconnecting means 2152 (e.g., second disconnecting means 2152) via which the second monitoring circuit 2146 is operable to disable the module 2104. As it shall be appreciated, disabling the module 2104 may include disconnecting the energy storage cells 2106 of that module 2104, e.g., from power port (e.g., terminals 2118 and 2120) of the module 2104. The second disconnecting means 2152 may be implemented as a switch and/or it may be implemented as a fuse.

The disabling device 2152 in this example is shown as a part of a fuse 2150 controllable via the second monitoring circuit 2146 and the fuse is arranged in line between the high polarity terminal of the cells 2106 and high side of the switching device 2126, such that when the fuse is triggered, the respective cells 2106 are prevented from connecting to the power bus 2124. The fuse 2150 in this non-limiting example is sensitive to overtemperature and can be e.g., a melting fuse and/or a chemical fuse. In order to disable a defective module 2104, the second monitoring circuit 2146 of that module activates a heater 2152, which when the temperature rise is high enough causes conductive path of the fuse 2150 to be broken, hence interrupting the current flow between the energy storage cells 2106 and the power port terminals 2118, 2120 of that module. It shall be appreciated that in some cases, the component 2150 and the and 2152 may collectively be known as a disabling device or fuse.

By tripping of the fuse 2150, the energy storage cells 2106 may be irreversibly disconnected from providing current via the power bus 2124. Thus, current is prevented to flow between the power port terminals 2018, 2020 and the energy storage cells 2106 until the fuse 2150 is replaced, e.g., after a safety inspection. The voltage regulator 2132 and the isolated gate driver 2130 in line with the power bus 2124 are also disconnected from the energy storage cells 2106, especially in terms of flow of current.

The second monitoring circuit 2146 may further be operable to generate an alert signal in response to any of the monitored physical parameters violating their respective threshold limit. This alert signal may be transmitted via the global alert line 2144 to the control circuit (PWM decoders) 2134 of all modules 2104 and/or to the control unit 2136. An advantage of doing so can be that the safety mechanism does not rely on the communication bus 2142 via which data from modules 2104 are normally received. Hence, even in cases when the bus 2142 is unavailable or the first monitoring system 2140 of a module 2104 is not responsive, the second monitoring system 2146 of that module can still bring the module 2104 and/or the whole unit 2100 in a safe state. Another advantage of providing this alert signal to the control circuit (PWM decoders) 2134 of all modules can be that sole reliance on the control unit 2136 for disabling the unit 2100 in response to an undesired state is avoided. Using the proposed approach, the control circuit 2134 of each module can disable their module in response to this alert signal on the global alert line 2144.

There may be provided at least one module 2104, a voltage sense circuit 2156 disposed to detect an overvoltage on the power bus 2124. The voltage sense circuit 2156 comprises a Zener diode 2158 which is arranged in blocking direction in from the high voltage line 2210 of the module 2104 towards a lower voltage (e.g., local ground or low voltage line 2212 of that module) in a way, that under normal conditions the Zener diode 2158 blocks current flowing from the module power line 2210 towards ground (e.g., local ground, e.g., line 2212). In case of an overvoltage at line 2210 the Zener diode 2158 will experience a reverse breakdown and a current will flow from the line 2210 through the Zener diode 2158. The current flow is transferred to an optocoupler 2154 to generate an alert signal transmitted via the global alert line 2144 in response to this reverse breakdown. The alert signal can be used to bring all modules 2104 in a safe state (e.g., disable). The alert signal may also be used to issue a warning, e.g., a fault signal which the electrical power unit 2100 can display to the user. Without limitation, some of the internal connections of the modules 2104 shown in FIG. 21 are not visible. FIG. 22 provides a more clear representation of such modules 2104. It shall be appreciated that in some non-limiting aspects, each module 2104 in the system 2100 may be of the same type. In FIG. 22, without limitations, certain signal names of certain lines are provided for illustration and ease of understanding. Alternatively, some or all modules 2104 in the system 2100 may be of dissimilar types although comprising similar monitoring concept as disclosed herein. The system 2100 may even comprise other components or other modules besides the modules 2104. The non-limiting example 2100 shown in FIG. 21 is meant to illustrate a system 2100 with similar modules 2104. Furthermore, it shall be appreciated that circuit 402, e.g., as shown in FIG. 5 and the block diagram of the module 2104 shown in FIG. 22 can relate to the same module. There are certain parts which can be directly correlated between the two FIGS., while certain different parts are visible in FIG. 22, for example, the second monitoring circuit (or second level battery monitor) and associated devices. Hence, the scheme shown in FIG. 21 is implementable on the circuit 402. Moreover, any blocks shown in FIG. 5 may be included in FIG. 22.

Even though the second monitoring circuit 2146 may be identical to the first monitoring circuit 2140, the applicant has found it to be advantageous to minimize the complexity of the second monitoring circuit 2146 such that it can be made fast and compact. Since it is advantageous for the module 2104 to be compact and lightweight, there can be a tradeoff between functionality of the second monitoring circuit 2146 and its compactness. This can also have influence of costs, not only bill-of-materials, but also production costs which typically increase with complexity. By inventive efforts the applicant has found the temperature monitoring as disclosed e.g., in FIGS. 15-20 to be especially advantageous when applied as temperature monitoring at the second monitoring circuit 2146. This not only allows monitoring circuit 2146 to react when any one of the cells 2106 may have abnormal temperature (e.g., overheating and/or underheating), but also when overall temperature of a group of cells 2106 (e.g., some or all) have abnormal temperature. The present teachings thus allow the second monitoring circuit 2146 to use significantly fewer measurement channels (e.g., single channel connected to the measurement tap) to achieve safety goals independently of the first monitoring circuit 2140, whereas the first monitoring circuit 2140 may perform individual cell level temperature tracking and have other mechanism to bring the module 2104 in a safe state. This can save significant costs and precious weight and space to achieve compact module 2104 which offers enhanced reliability in terms of safety while the second monitoring circuit 2146 still having actionable temperature visibility on individual cell level. Furthermore, when the teachings of FIGS. 6-14 are further combined, they can synergistically enhance compactness of the module 2104 while having temperature visibility at both monitoring circuits 2140 and 2146 by arranging the various temperature sensors without consuming significant space between the cells.

In view of certain non-limiting aspects of present teachings (e.g., FIG. 21), it shall that there can be provided an energy module 2104. The energy module 2104 comprises a plurality of electrical energy storage cells 2106. The energy module 2104 also comprises a first battery monitor circuit 2140 which is configured to measure a temperature of each cell of the plurality of electrical energy storage cells 2106. The energy module 2104 further comprises a second battery monitor circuit 2146. The energy module 2104 also comprises at least one electronic device (e.g., 2150, 2152, 2154). The second battery monitor circuit 2146 is operatively coupled to (or second battery monitor circuit 2146 comprises) a plurality of temperature sensors (e.g., 1202, 1402-1408) configured to monitor temperatures of the plurality of electrical energy storage cells 2106. The temperature sensors 1202, 1402-1408 are arranged in a network such that each temperature sensor shares a current or voltage with at least another temperature sensor. A measurement tap (e.g., 1512) is provided in the network, which tap has a signal value that will change responsive to a change of the shared current or voltage. The change in the shared current or voltage is caused by the temperatures of the electrical energy storage cells 2106 being monitored. The second battery monitor circuit 2146 also comprises a circuit configured to detect an occurrence of a temperature error that is associated with one or more energy storage cells 2106 based on the signal value at the measurement tap 1512. Any one or more of the electronic devices 2150, 2154, 2154 are controlled (e.g., in response to the temperature error) by the second battery monitor circuit 2146 to (i) disconnect the plurality of electrical energy storage cells 2106 from an output terminal 2118, 2120 and/or (ii) cause the energy module 2104 to be disabled. The electronic device can include, but is not limited to, a heater 2152, a switch 2150, fuse 2150 and/or an optocoupler 2154.

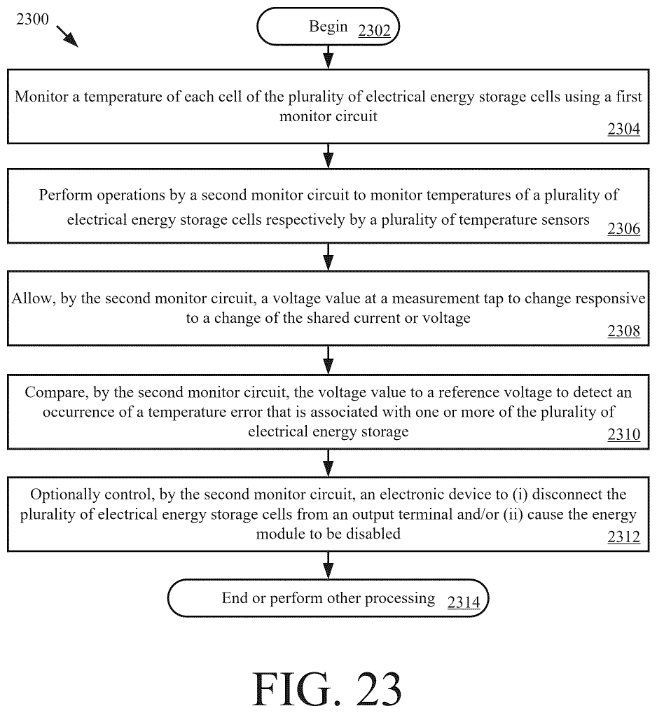

FIG. 23 provides a flow diagram of a method 2300 for operating an energy module (e.g., energy module 2104 of FIG. 21). Method 2300 begins at block 2302 and continues to block 2304 where a first monitor circuit (e.g., first monitor circuit 2140 of FIG. 21) monitors a temperature of each cell of the plurality of electrical energy storage cells (e.g., cells 2106 of FIG. 21). Next in block 2306, a second monitor circuit performs (e.g., second monitor circuit 2146) operations to monitor temperatures of the electrical energy storage cells respectively by a plurality of temperature sensors (e.g., temperature sensors 1402-1408 of FIGS. 14A-15, 17 and/or temperature sensors of FIG. 18). The temperature sensors are arranged in a network such that each temperature sensor shares a current or voltage with at least another temperature sensor in the plurality of temperature sensors.

In block 2308, the second monitor circuit allows a voltage value at a measurement tap (e.g., measurement tap 1512 e.g., of FIG. 15A, Measurement Tap e.g., in FIG. 15B, or voltage tap e.g., in FIG. 18) to change responsive to a change of the shared current or voltage. The change in the shared current or voltage is caused by the temperatures of the plurality of electrical energy storage cells being monitored.

In block 2310, the second monitor circuit compares the voltage value to a reference voltage to detect an occurrence of a temperature error that is associated with one or more of the plurality of electrical energy storage. The second monitor circuit may also control an electronic device (e.g., device 2150, 2152 and/or 2154 of FIG. 21) to (i) disconnect the plurality of electrical energy storage cells from an output terminal and/or (ii) cause the energy module to be disabled. Subsequently, method 2300 continues to block 2314 where it ends or other operations are performed. For example, the operation may repeat any of the steps, e.g., restart from block 2302.

In view of certain non-limiting aspects of present teachings (e.g., FIG. 23), it shall that there can be provided implementing systems and methods 2300 for operating an energy module 2104. The methods may comprise: monitoring a temperature of each cell of the plurality of electrical energy storage cells 2106 using a first monitor circuit 2140; and performing operations by a second monitor circuit 2146 to (i) monitor temperatures of a plurality of electrical energy storage cells 2106 respectively by a plurality of temperature sensors (e.g., 1202, 1402-1408). The temperature sensors 1202, 1402-1408 may be arranged in a network such that each temperature sensor shares a current or voltage with at least another temperature sensor. (ii) allow a voltage value at a measurement tap (e.g., 1512) to change responsive to a change of the shared current or voltage. The change in the shared current or voltage may be caused by the temperatures of the electrical energy storage cells 2106 being monitored. (iii) compare the voltage value to a reference voltage to detect an occurrence of a temperature error that is associated with one or more of the electrical energy storage cells 2106. The methods may also comprise controlling (e.g., in response to the temperature error), by the second monitor circuit 2146, at least one electronic device (e.g., 2150, 2154, 2154) to (i) disconnect the electrical energy storage cells 2106 from an output terminal 2118, 2120 and/or (ii) cause the energy module 2104 to be disabled. The electronic device can include, but is not limited to, a heater 2152, a switch 2150, fuse 2150 and/or an optocoupler 2154.

The present disclosure also concerns with an electrical system (e.g., a power supply) comprising at least one module 2104. The herein disclosed methods may be implemented via any suitable electrical system (e.g., a power supply). The methods may even be at least partially executable via a suitable electrical system (e.g., control unit 2136 and/or any other related processor). The electrical system may either be a self-contained (e.g., independent) system (e.g., a power supply), or it may be part of a larger system, e.g., an electric vehicle (“EV”). It shall be appreciated that the present teachings can be especially advantageous for portable electrical system, e.g., a portable power supply, of which compactness and lightweight are desired properties.

Although the present solution has been illustrated and described with respect to one or more implementations, equivalent alterations and modifications will occur to others skilled in the art upon the reading and understanding of this specification and the annexed drawings. In addition, while a particular feature of the present solution may have been disclosed with respect to only one of several implementations, such feature may be combined with one or more other features of the other implementations as may be desired and advantageous for any given or particular application. Thus, the breadth and scope of the present solution should not be limited by any of the above described scenarios. Rather, the scope of the present solution should be defined in accordance with the following claims and their equivalents.

Without excluding further possible embodiments, certain example embodiments are summarized in the following clauses:
Clause 1: An energy module, comprising: a plurality of electrical energy storage cells; a plurality of temperature sensors configured to monitor temperatures of the plurality of electrical energy storage cells (e.g., the plurality of temperature sensors being arranged in a network such that each temperature sensor shares a current or voltage with at least another temperature sensor in the plurality of temperature sensors); a measurement tap in the network, which has a signal value that will change responsive to a change of the shared current or voltage (e.g., wherein the change in the shared current or voltage is caused by the temperatures of the plurality of electrical energy storage cells being monitored); and a circuit configured to detect an occurrence of a temperature error that is associated with one or more of the plurality of energy storage cells based on the signal value at the measurement tap.
Clause 1a. An energy module, comprising: a plurality of electrical energy storage cells; a first battery monitor circuit configured to measure a temperature of each cell of the plurality of electrical energy storage cells; a second battery monitor circuit; and an electronic device. The second battery monitor circuit comprises: a plurality of temperature sensors configured to monitor temperatures of the plurality of electrical energy storage cells, the plurality of temperature sensors being arranged in a network such that each temperature sensor shares a current or voltage with at least another temperature sensor in the plurality of temperature sensors; a measurement tap in the network, which has a signal value that will change responsive to a change of the shared current or voltage, wherein the change in the shared current or voltage is caused by the temperatures of the plurality of electrical energy storage cells being monitored; and a circuit configured to detect an occurrence of a temperature error that is associated with one or more of the plurality of energy storage cells based on the signal value at the measurement tap. The electronic device is controlled by the second battery monitor circuit to (i) disconnect the plurality of electrical energy storage cells from an output terminal and/or (ii) cause the energy module to be disabled.
Clause 1b. The energy module of clause 1a, wherein the electronic device comprises any one or more of: a heater, a switch, fuse and/or an optocoupler.
Clause 2: The energy module of any of the preceding clauses, wherein the circuit detects an occurrence of the temperature error by comparing the signal value (e.g., a voltage) to a reference value (e.g., a reference voltage value).
Clause 3: The energy module of any of the preceding clauses, wherein the reference value (e.g., reference voltage value) is selected based on a qualitative correlation between possible measured temperature values of the plurality of temperature sensors and a threshold temperature value.
Clause 4: The energy module of any of the preceding clauses, wherein the network comprises a voltage divider.
Clause 5: The energy module of any of the preceding clauses, wherein the voltage divider comprises (1) a resistor connected between a first input line and the measurement tap and (2) the plurality of temperature sensors connected in parallel or series between the measurement tap and a second input line, wherein the first or second input line is connected to reference potential (e.g., ground potential) and the other input line to a voltage or current source.
Clause 6: The energy module of any of the preceding clauses, further comprising a current source connected between a first input line and the measurement tap, and wherein the plurality of temperature sensors are connected in parallel or series between the measurement tap and a second input line.
Clause 7: The energy module of any of the preceding clauses, wherein the temperature error comprises an overtemperature or an undertemperature of the energy module or one of the plurality of temperature sensors.
Clause 8: The energy module of any of the preceding clauses, wherein the overtemperature is detected using negative temperature coefficient sensors connected in parallel or positive temperature coefficient sensors connected in series.
Clause 9: The energy module of any of the preceding clauses, wherein the undertemperature is detected using negative temperature coefficient sensors connected in series or positive temperature coefficient sensors connected in parallel.
Clause 10: The energy module of any of the preceding clauses, wherein each of the plurality of temperature sensors is mounted to a surface of a circuit board that is (i) internal to the energy module and (ii) spaced apart from the plurality of electrical energy storage cells.
Clause 11: The energy module of any of the preceding clauses, wherein a temperature and/or resistance of a respective temperature sensor of the plurality of temperature sensors changes responsive to heat thermally conducted from one or more of the plurality of energy storage cells to a substrate of the circuit board.
Clause 12: A method for operating an energy module, comprising: monitoring temperatures of a plurality of electrical energy storage cells respectively by a plurality of temperature sensors (e.g., plurality of temperature sensors are arranged in a network such that each temperature sensor shares a current or voltage with at least another temperature sensor in the plurality of temperature sensors); allowing a voltage value at a measurement tap to change responsive to a change of the shared current or voltage, wherein the change in the shared current or voltage is caused by the temperatures of the plurality of electrical energy storage cells being monitored; and comparing the voltage value to a reference voltage to detect an occurrence of a temperature error that is associated with one or more of the plurality of electrical energy storage.
Clause 12a. A method for operating an energy module, comprising: monitoring a temperature of each cell of the plurality of electrical energy storage cells using a first monitor circuit; and performing operations by a second monitor circuit to (i) monitor temperatures of a plurality of electrical energy storage cells respectively by a plurality of temperature sensors, wherein plurality of temperature sensors are arranged in a network such that each temperature sensor shares a current or voltage with at least another temperature sensor in the plurality of temperature sensors, (ii) allow a voltage value at a measurement tap to change responsive to a change of the shared current or voltage, wherein the change in the shared current or voltage is caused by the temperatures of the plurality of electrical energy storage cells being monitored, and (iii) compare the voltage value to a reference voltage to detect an occurrence of a temperature error that is associated with one or more of the plurality of electrical energy storage cells; and controlling, by the second monitor circuit, an electronic device to (i) disconnect the plurality of electrical energy storage cells from an output terminal and/or (ii) cause the energy module to be disabled.
Clause 12b. The energy module of clause 12a, wherein the electronic device may comprise a heater, a switch, and/or an optocoupler.
Clause 13: The method of any of the preceding method clauses, further comprising selecting the reference voltage based on a correlation between possible measured temperature values of the plurality of temperature sensors and a threshold temperature value.
Clause 14. The method of any of the preceding method clauses, wherein the network comprises a voltage divider.
Clause 15: The method of any of the preceding method clauses, wherein the voltage divider comprises (1) a resistor connected between a first input line and the measurement tap and (2) the plurality of temperature sensors connected in parallel or series between the measurement tap and a second input line, the first or second input line being connected to ground or a reference potential and the other input one to a DC voltage supply.
Clause 16: The method of any of the preceding method clauses, wherein the network comprises a current source connected between a first input line and the measurement tap, and wherein the plurality of temperature sensors are connected in parallel or series between the measurement tap and a second input line.
Clause 17: The method of any of the preceding method clauses, wherein the temperature error comprises an over temperature or an undertemperature of the energy module or one of the plurality of temperature sensors.
Clause 18: The method of any of the preceding method clauses, wherein the over temperature is detected using negative temperature coefficient sensors connected in parallel or positive temperature coefficient sensors connected in series.
Clause 19: The method of any of the preceding method clauses, wherein undertemperature is detected using negative temperature coefficient sensors connected in series or positive temperature coefficient sensors connected in parallel.
Clause 20: The method of any of the preceding method clauses, wherein each of the plurality of temperature sensors comprises a sensor mounted to a surface of a circuit board that is (i) internal to the energy module and (ii) spaced apart from the plurality of electrical energy storage cells, and a temperature and/or resistance of a respective temperature sensor of the plurality of temperature sensors changes responsive to heat thermally communicated from one or more of the plurality of energy storage cells to a substrate of the circuit board.
Clause 21: A system (e.g., an energy module) comprising means for performing the steps of any of the above method clauses.
Clause 22: A software product comprising instructions which when executed by one or more suitable processors (e.g., those of a system (e.g., control unit) and/or an energy module) cause any of the processors to perform the steps of any of the above method clauses.
Clause 23: An electrical system (e.g., a power supply, power supply unit) comprising at least one energy module of any of the above Clauses.
Clause 24: An electrical system (e.g., an electric vehicle (“EV”), a power supply, a portable power supply) comprising a plurality of energy modules according to any of the above Clauses.

The breadth and scope of this disclosure should not be limited by any of the above-described example embodiments, but should be defined only in accordance with the following claims and their equivalents.

1. An energy module, comprising:
a plurality of electrical energy storage cells;
a first battery monitor circuit configured to measure a temperature of each cell of the plurality of electrical energy storage cells;
a second battery monitor circuit comprising:
a plurality of temperature sensors configured to monitor temperatures of the plurality of electrical energy storage cells, the plurality of temperature sensors being arranged in a network such that each temperature sensor shares a current or voltage with at least another temperature sensor in the plurality of temperature sensors;
a measurement tap in the network, which has a signal value that will change responsive to a change of the shared current or voltage, wherein the change in the shared current or voltage is caused by the temperatures of the plurality of electrical energy storage cells being monitored; and
a circuit configured to detect an occurrence of a temperature error that is associated with one or more of the plurality of energy storage cells based on the signal value at the measurement tap; and
an electronic device that is controlled by the second battery monitor circuit to (i) disconnect the plurality of electrical energy storage cells from an output terminal and/or (ii) cause the energy module to be disabled.

2. The energy module according to claim 1, wherein the circuit detects an occurrence of the temperature error by comparing the signal value to a reference value.

3. The energy module according to claim 2, wherein the reference value is selected based on a correlation between possible measured temperature values of the plurality of temperature sensors and a threshold temperature value.

4. The energy module according to claim 1, wherein the network comprises a voltage divider, which voltage divider comprises (1) a resistor connected between a first input line and the measurement tap and (2) the plurality of temperature sensors connected in parallel or series between the measurement tap and a second input line, wherein the first or second input line is connected to reference potential and the other input line to a voltage source or a current source.

5. The energy module according to claim 1, wherein the temperature error comprises an overtemperature or an undertemperature of the energy module or one of the plurality of temperature sensors.

6. A method for operating an energy module, comprising:
monitoring temperatures of a plurality of electrical energy storage cells respectively by a plurality of temperature sensors, wherein plurality of temperature sensors are arranged in a network such that each temperature sensor shares a current or voltage with at least another temperature sensor in the plurality of temperature sensors;
allowing a voltage value at a measurement tap to change responsive to a change of the shared current or voltage, wherein the change in the shared current or voltage is caused by the temperatures of the plurality of electrical energy storage cells being monitored; and
comparing the voltage value to a reference voltage to detect an occurrence of a temperature error that is associated with one or more of the plurality of electrical energy storage.

7. The method according to claim 6, further comprising selecting the reference voltage based on a qualitative correlation between possible measured temperature values of the plurality of temperature sensors and a threshold temperature value.

8. The method according to claim 1, wherein the network comprises a voltage divider.

9. The method according to claim 8, wherein the voltage divider comprises (1) a resistor connected between a first input line and the measurement tap and (2) the plurality of temperature sensors connected in parallel or series between the measurement tap and a second input line, the first or second input line being connected to a reference potential and the other input one to a voltage or current source.

10. The method according to claim 6, wherein the network comprises a current source connected between a first input line and the measurement tap, and wherein the plurality of temperature sensors are connected in parallel or series between the measurement tap and a second input line.

11. The method according to claim 6, wherein the temperature error comprises an over temperature or an undertemperature of the energy module or one of the plurality of temperature sensors.

12. The method according to claim 11, wherein the over temperature is detected using negative temperature coefficient sensors connected in parallel or positive temperature coefficient sensors connected in series.

13. The method according to claim 11, wherein undertemperature is detected using negative temperature coefficient sensors connected in series or positive temperature coefficient sensors connected in parallel.

14. The method according to claim 6, wherein each of the plurality of temperature sensors comprises a sensor mounted to a surface of a circuit board that is (i) internal to the energy module and (ii) spaced apart from the plurality of electrical energy storage cells, and a temperature and/or resistance of a respective temperature sensor of the plurality of temperature sensors changes responsive to heat thermally communicated from one or more of the plurality of energy storage cells to a substrate of the circuit board.

15. A system comprising means for performing the steps of claim 6.

16. The method according to claim 12, wherein undertemperature is detected using negative temperature coefficient sensors connected in series or positive temperature coefficient sensors connected in parallel.

17. The method according to claim 1, wherein the electronic device comprises any one or more of a heater, a switch, fuse and/or optocoupler.

18. The method according to claim 5, wherein the overtemperature is detected using negative temperature coefficient sensors connected in parallel or positive temperature coefficient sensors connected in series.

19. The method according to claim 5, wherein the undertemperature is detected using negative temperature coefficient sensors connected in series or positive temperature coefficient sensors connected in parallel.

20. The method according to claim 1, wherein each of the plurality of temperature sensors is mounted to a surface of the circuit board that is (i) internal to the energy module and (ii) spaced apart from the plurality of electrical energy storage cells, and a temperature and/or resistance of a respective temperature sensor of the plurality of temperature sensors changes responsive to heat thermally conducted from one or more of the plurality of energy storage cells to a substrate of the circuit board.
